(19) United States
(12) Patent Application Publication
(10) Pub. No.: US 2010/0129989 A1
(43) Pub. Date: May 27, 2010

(54) DICING DIE-BONDING FILM AND PROCESS FOR PRODUCING SEMICONDUCTOR DEVICE

(75) Inventors: Katsuhiko Kamiya, Osaka (JP); Hironao Ootake, Osaka (JP); Takeshi Matsumura, Osaka (JP); Shuuhei Murata, Osaka (JP)

Correspondence Address: SUGHRUE-265550, 2100 PENNSYLVANIA AVE. NW, WASHINGTON, DC, 20037-3213, US

(73) Assignee: NITTO DENKO CORPORATION, Osaka (JP)

(21) Appl. No.: 12/625,820

(22) Filed: Nov. 25, 2009

(30) Foreign Application Priority Data
Nov. 26, 2008 (JP) 2008-301559

(51) Int. Cl. H01L 21/78; B32B 5/18; B32B 5/16

(52) U.S. Cl. 438/464; 428/317.5; 428/313.3; 257/E21.599

(57) ABSTRACT

The present invention relates to a dicing die-bonding film comprising: a dicing film having a pressure-sensitive adhesive layer provided on a base material; and a die-bonding film provided on the pressure-sensitive adhesive layer, in which the pressure-sensitive adhesive layer of the dicing film is an active energy ray-curable heat-expandable pressure-sensitive adhesive layer containing a foaming agent, and in which the die-bonding film is constituted by a resin composition containing an epoxy resin. Moreover, the present invention provides a process for producing a semiconductor device which includes using the above-described dicing die-bonding film.

### FIELD OF THE INVENTION

The present invention relates to a dicing die-bonding film that is used for dicing a workpiece by providing an adhesive for fixing a chip-shaped workpiece (such as a semiconductor chip) and an electrode member onto the workpiece (such as a semiconductor wafer) before dicing.

### BACKGROUND OF THE INVENTION

A semiconductor wafer (workpiece) where a circuit pattern is formed is diced into semiconductor chips (chip-shaped workpiece) (a dicing step) after the thickness thereof is adjusted by backside polishing according to needs. In the dicing step, the semiconductor wafer is generally washed with an appropriate liquid pressure (normally, about 2 kg/cm²) in order to remove a cut layer. The semiconductor chip is then fixed onto an adherend such as a lead frame with an adhesive (a mounting step), and then transferred to a bonding step. In the conventional mounting step, the adhesive has been applied onto the lead frame or the semiconductor chip. However, in this method, it is difficult to make the adhesive layer uniform and a special apparatus and a long period of time are required for the application of the adhesive. For this reason, there has been proposed a dicing die-bonding film, which adhesively holds the semiconductor wafer in the dicing step and also imparts an adhesive layer for fixing a chip that is necessary in the mounting step (for example, see JP-A-60-57642).

In the dicing die-bonding film described in JP-A-60-57642, an adhesive layer is formed on a supporting base material so that the adhesive layer can be peeled from the supporting base material. That is, the dicing die-bonding film is made so that after the semiconductor wafer is diced while being held by the adhesive layer, each of the semiconductor chips is peeled together with the adhesive layer by stretching the supporting base material and individually recovered, and it is then fixed onto an adherend such as a lead frame with the adhesive layer.

For this type of the adhesive layer of the dicing die-bonding film, such a good holding power toward the semiconductor wafer that a dicing failure, a dimensional error, etc. do not occur, such a good peeling ability that the semiconductor chip after dicing can be peeled from the supporting base material integrally with the adhesive layer, and such low fouling properties that no adhesive is attached to the semiconductor wafer and the adhesive layer after peeling are desired. However, it has been by no means easy to exhibit these characteristics with good balance. Particularly, in the case where a large holding power is required for the adhesive layer as in the method of dicing the semiconductor wafer with a rotary round blade, it has been difficult to obtain a dicing die-bonding film that satisfies the above characteristics.

Therefore, in order to overcome such problems, various improved methods have been proposed (for example, see JP-A-2-248064). In JP-A-2-248064, a pressure-sensitive adhesive layer that can be cured by ultraviolet rays is interposed between a supporting base material and a adhesive layer. In the method therein, the pressure-sensitive adhesive layer is cured by ultraviolet ray after the dicing so that the adhesive force between the pressure-sensitive adhesive layer and the adhesive layer is decreased, and the both layers are then peeled from each other to facilitate picking-up of the semiconductor chip.

However, even by this improved method, it is sometimes difficult to prepare a dicing die-bonding film that well balances the holding power at the dicing and the peeling ability needed afterward. For example, in the case where a large semiconductor chip having a size of 10 mm×10 mm or larger is to be obtained, it is not easy to pick up the semiconductor chip by means of a common die bonder since the size of the semiconductor chip is so large.

### SUMMARY OF THE INVENTION

The invention has been made in view of the above problems, and an object thereof is to provide a dicing die-bonding film that is excellent in balancing characteristics among holding power even at the time of dicing a thin workpiece, peeling ability at the time of integrally peeling a semiconductor chip obtained by the dicing together with the die-bonding film, and such low fouling properties that no pressure-sensitive adhesive component is attached to the semiconductor wafer and the adhesive layer after the peeling.

The inventors of the present application have investigated a dicing die-bonding film in order to solve the above conventional problems. As a result, it has been found that, when a dicing die-bonding film having a form containing a dicing film whose pressure-sensitive adhesive layer is composed of an active energy ray-curable heat-expandable pressure-sensitive adhesive layer and a die-bonding film constituted by an epoxy resin composition is used, balance characteristics among holding power for holding a thin workpiece to effectively dice the workpiece, peeling ability for easily peeling a semiconductor chip obtained by the dicing together with the die-bonding film integrally, and low fouling properties for suppressing or preventing the attachment of the pressure-sensitive adhesive component to the semiconductor wafer and the die-bonding film (adhesive layer) after the peeling is excellent. Thus, the invention has been completed.

Namely, the present invention relates to

a dicing die-bonding film including:

a dicing film having a pressure-sensitive adhesive layer provided on a base material; and

a die-bonding film provided on the pressure-sensitive adhesive layer,

in which the pressure-sensitive adhesive layer of the dicing film is an active energy ray-curable heat-expandable pressure-sensitive adhesive layer containing a foaming agent, and

in which the die-bonding film is constituted by a resin composition containing an epoxy resin.

As above, since the pressure-sensitive adhesive layer of the dicing film in the dicing die-bonding film of the invention is an active energy ray-curable heat-expandable pressure-sensitive adhesive layer, the dicing die-bonding film has heat expandability and active energy ray curability. Therefore, reduction of peeling power can be achieved owing to the heat expandability, so that the peeling ability is good and good pick-up properties can be enabled. In addition, low fouling properties can be improved owing to the active energy ray curability. Of course, the active energy ray-curable heat-expandable pressure-sensitive adhesive layer has pressure-sensitive adhesiveness (holding power) and thus can well hold the thin workpiece (semiconductor wafer) when diced. In addition, since the die-bonding film is attached to the semiconductor wafer after peeling, a semiconductor chip can be adhered and fixed to a prescribed adherend using the die-bonding film in the next step and a semiconductor device can subsequently be produced by effectively performing appropriate treatment(s) and the like after the next step.

In the invention, a heat-expandable microsphere can be suitably used as the foaming agent.

Moreover, it is preferable that the active energy ray-curable heat-expandable pressure-sensitive adhesive layer of the dicing film is formed of an active energy ray-curable heat-expandable pressure-sensitive adhesive containing the following acrylic polymer A and that the active energy ray-curable heat-expandable pressure-sensitive adhesive layer of the dicing film has a gel fraction after curing by active energy ray irradiation of 90% by weight or more.

Acrylic polymer A: an acrylic polymer having a constitution that a polymer composed of a monomer composition containing 50% by weight or more of an acrylic acid ester represented by CH₂═CHCOOR (wherein R is an alkyl group having 6 to 10 carbon atoms) and 10% by weight to 30% by weight of a hydroxyl group-containing monomer and containing no carboxyl group-containing monomer is addition reacted with an isocyanate compound having a radical-reactive carbon-carbon double bond in an amount of 50 mol % to 95 mol % based on the hydroxyl group-containing monomer.

As above, in the acrylic polymer A as a base polymer of the active energy ray-curable heat-expandable pressure-sensitive adhesive layer, CH₂═CHCOOR (in which R is an alkyl group having 6 to 10 carbon atoms) is used as an acrylic acid ester in the monomer composition. Accordingly, a decrease in pick-up properties due to excessively large peeling force can be prevented. Moreover, in addition to the adjustment of the ratio of the hydroxyl group-containing monomer to the range of 10% by weight to 30% by weight, the ratio of the isocyanate compound having a radical-reactive carbon-carbon double bond is adjusted to the range of 50 mol % to 95 mol % based on the hydroxyl group-containing monomer and the gel fraction after curing by active energy ray irradiation is controlled to 90% by weight or more. Accordingly, a decrease in pick-up properties and low fouling properties can be effectively prevented.

In the dicing die-bonding film of the invention, it is preferable that the active energy ray-curable heat-expandable pressure-sensitive adhesive layer of the dicing film is formed of an active energy ray-curable heat-expandable pressure-sensitive adhesive containing an active energy ray-curable pressure-sensitive adhesive capable of forming an active energy ray-curable pressure-sensitive adhesive layer having an elastic modulus in a temperature range of 23° C. to 150° C. of 5×10⁴ Pa to 1×10⁶ Pa, and a foaming agent; and that the die-bonding film has an elastic modulus in a temperature range of T₀ to T₀+20° C. of 1×10⁵ Pa to 1×10¹⁰ Pa, in which T₀ represents a foaming starting temperature of the active energy ray-curable heat-expandable pressure-sensitive adhesive layer of the dicing film. By controlling the elastic modulus of the active energy ray-curable heat-expandable pressure-sensitive adhesive layer (particularly, elastic modulus of the acrylic polymer A) of the dicing film to the above range, heat expandability becomes good and the decrease in the pick-up properties can be prevented. Moreover, by controlling the elastic modulus of the die-bonding film to the above range, inhibition of decrease in contact area between the dicing film and the die-bonding film resulting from heat expansion can be prevented and thus the contact area between the dicing film and the die-bonding film can be effectively decreased.

Moreover, the invention provides a process for producing a semiconductor device which comprises using the above-described dicing die-bonding film.

The dicing die-bonding film of the invention is excellent in balancing characteristics among holding power even at the time of dicing a thin workpiece, peeling ability at the time of integrally peeling a semiconductor chip obtained by the dicing together with the die-bonding film, and such low fouling properties that no pressure-sensitive adhesive component is attached to the semiconductor wafer and the adhesive layer after the peeling. Furthermore, after the peeling, since the die-bonding film is attached to the semiconductor chip, the semiconductor chip can be adhered and fixed using the die-bonding film in the next step.

The dicing die-bonding film of the invention can be used at the time when a workpiece is diced, in such a state that an adhesive for fixing a chip-shaped workpiece such as a semiconductor chip to an electrode member is provided beforehand onto a workpiece such as a semiconductor wafer before dicing. By the use of the dicing die-bonding film of the invention, it becomes possible to easily produce a semiconductor device in which a semiconductor chip is fixed to an electrode member.

### BRIEF DESCRIPTION OF THE DRAWINGS

FIG. 1 is a cross-sectional schematic view showing a dicing die-bonding film according to one embodiment of the invention.

FIG. 2 is a cross-sectional schematic view showing a dicing die-bonding film according to another embodiment of the invention.

FIGS. 3A to 3E are cross-sectional schematic views showing an example in which a semiconductor chip is mounted on a dicing die-bonding film through a die-bonding film.

### DESCRIPTION OF REFERENCE NUMERALS AND SIGNS

10, 11 dicing die-bonding film
1a base material
1b active energy ray-curable heat-expandable pressure-sensitive adhesive layer
2 dicing film
3, 31 die-bonding film
4 semiconductor wafer
5 semiconductor chip
6 adherend
7 bonding wire
8 sealing resin
9 spacer

### DETAILED DESCRIPTION OF THE INVENTION

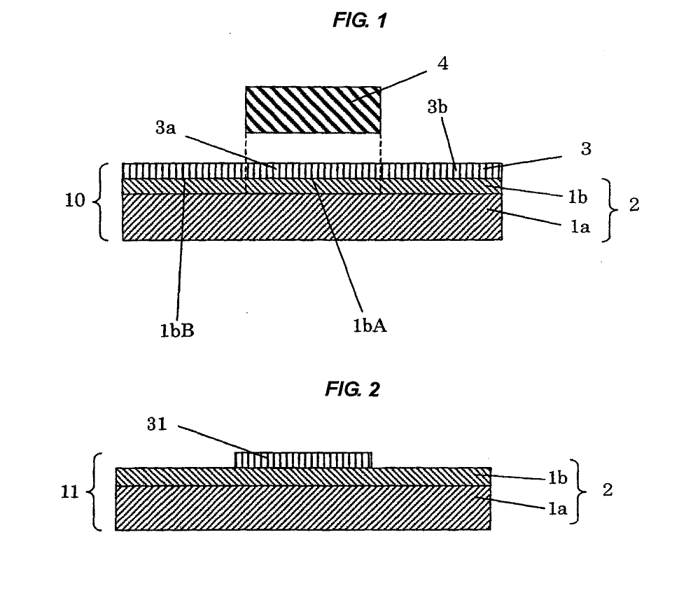

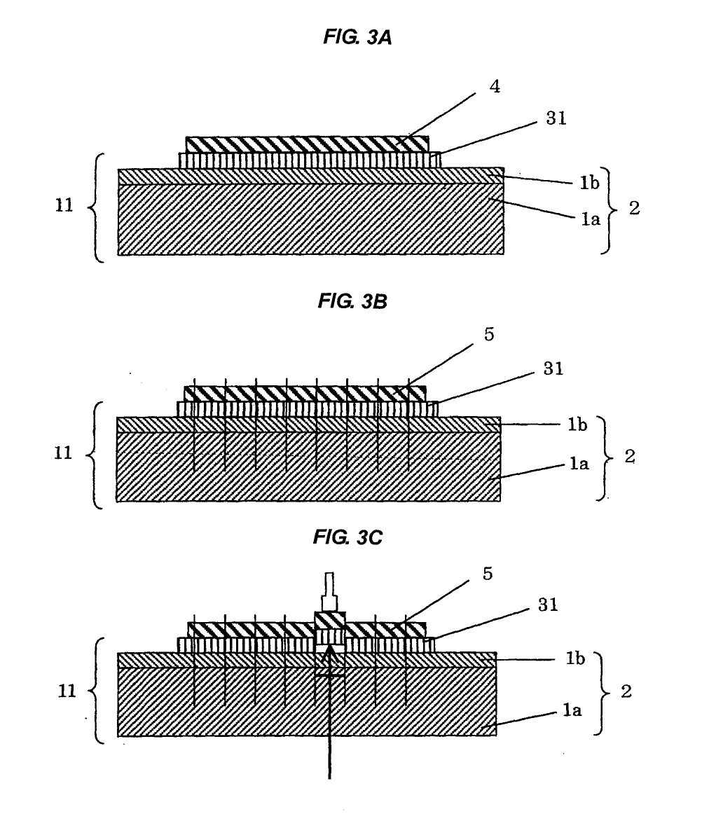

Embodiments of the present invention are described with reference to FIGS. 1 and 2 but the invention is not limited to these embodiments. FIG. 1 is a cross-sectional schematic view showing one embodiment of the dicing die-bonding film of the invention. FIG. 2 is a cross-sectional schematic view showing another embodiment of the dicing die-bonding film of the invention. However, parts that are unnecessary for the description are not given, and there are parts shown by magnifying, minifying, etc. in order to make the description easy.

As shown in FIG. 1, the dicing die-bonding film of the invention is a dicing die-bonding film 10 having a constitution containing a dicing film 2 in which an active energy ray-curable heat-expandable pressure-sensitive adhesive layer 1b is provided on a base material 1a and a die-bonding film 3 provided on the active energy ray-curable heat-expandable pressure-sensitive adhesive layer 1b. Further, the dicing die-bonding film of the invention may be a dicing die-bonding film 11 having a constitution that a die-bonding film 31 is formed not over the whole surface of the active energy ray-curable heat-expandable pressure-sensitive adhesive layer 1b but only on a semiconductor wafer attaching part as shown in FIG. 2.

### (Dicing Film)

(Base Material)

It is important that the base material has active energy ray transparency. The base material is a strength matrix of the dicing die-bonding film. The base material is not particularly limited as long as it has the active energy ray transparency. Examples thereof include polyolefins such as low-density polyethylene, straight chain polyethylene, medium-density polyethylene, high-density polyethylene, very low-density polyethylene, random copolymer polypropylene, block copolymer polypropylene, homopolypropylene, polybutene, and polymethylpentene; ethylene-vinylacetate copolymers; ionomer resins; ethylene-(meth)acrylic acid copolymers; ethylene-(meth)acrylic acid ester (random or alternating) copolymers; ethylene-butene copolymers; ethylene-hexene copolymers; acrylic resins; polyurethanes; polyesters such as polyethylene terephthalate and polyethylene naphthalate; polycarbonates; polyimides; polyether ether ketones; polyetherimide; polyamide; whole aromatic polyamides; polyphenyl sulfide; aramid (paper); glass; glass cloth; fluorinated resins; polyvinyl chloride; polyvinylidene chloride; ABS (acrylonitrile-butadiene-styrene copolymer); cellulose resins; silicone resins; metal (foil); and paper.

Moreover, as the material of the base material, a polymer such as a cross-linked body of each of the above resins can also be used.

A plastic film derived from each of the resins may be used unstretched, or may be used after applying a monoaxial or biaxial stretching treatment according to needs. According to resin sheets to which heat shrinkable properties are imparted by a stretching treatment, etc., the adhesion area between the active energy ray-curable heat-expandable pressure-sensitive adhesive layer and the die-bonding film is reduced by heat shrinkage of the base material after dicing, whereby the collection of the semiconductor chips can be effectively facilitated.

As the base material, a sheet formed of a transparent resin, a sheet having a reticulate structure, a sheet on which holes are opened, etc. can be used.

A commonly used surface treatment, e.g., a chemical or physical treatment such as a chromate treatment, ozone exposure, flame exposure, exposure to high-voltage electric shock, and an ionized radiation treatment, and a coating treatment with an undercoating agent (for example, a tacky substance to be described later) can be applied on the surface of the base material in order to improve adhesiveness with the adjacent layer, holding properties, etc.

The same type or different type of resins can be appropriately selected and used for forming the base material, and a blended resin in which resins of plural types are blended may be used according to needs. Further, a vapor-deposited layer of a conductive substance composed of a metal, an alloy, an oxide thereof, etc. and having a thickness of about 30 to 500 Angstrom may be provided on the base material in order to impart an antistatic function to the base material. The base material may have a form of a single layer or a multi layer composed of two or more types.

The thickness of the base material can be appropriately determined without particular limitation. However, it is generally about 5 to 200 μm.

Incidentally, the base material may contain various additives (colorants, fillers, plasticizers, antiaging agents, antioxidants, surfactants, flame retardants, etc.) within the range where the advantages and the like of the invention are not impaired.

(Active Energy Ray-Curable Heat-Expandable Pressure-Sensitive Adhesive Layer)

The active energy ray-curable heat-expandable pressure-sensitive adhesive layer has pressure-sensitive adhesiveness as well as active energy ray curability and heat expandability and can be formed of an active energy ray-curable heat-expandable pressure-sensitive adhesive (composition). The active energy ray-curable heat-expandable pressure-sensitive adhesive can easily decrease its pressure-sensitive adhesive force by increasing the degree of crosslinking by active energy ray irradiation. In this connection, in the invention, by irradiating only a part of the active energy ray-curable heat-expandable pressure-sensitive adhesive layer corresponding to a semiconductor wafer attaching part through the die-bonding film (a part 1bA in FIG. 1) with an active energy ray, a difference in the pressure-sensitive adhesive force from another part (a semiconductor wafer non-attaching part through the die-bonding film) (a part 1bB in FIG. 1) may also be provided.

Moreover, by irradiating a part to which a die-bonding film 31 shown in FIG. 2 is to be attached to cure the active energy ray-curable heat-expandable pressure-sensitive adhesive layer 1b in advance, a part where the pressure-sensitive adhesive force is remarkably decreased can be easily formed. In this case, since the die-bonding film 31 is attached on the part where the pressure-sensitive adhesive force has been decreased by curing, the interface between the pressure-sensitive adhesive force-decreased part of the active energy ray-curable heat-expandable pressure-sensitive adhesive layer 1b (a part corresponding to the part 1bA in FIG. 1) and the die-bonding film 31 can exhibit a characteristic of being low fouling and more easily peeled (peeling ability) during picking-up. On the other hand, in the active energy ray-curable heat-expandable pressure-sensitive adhesive layer 1b, the part which has not been irradiated with an active energy ray (a part corresponding to the part 1bB in FIG. 1) has a sufficient pressure-sensitive adhesive force.

As described above, in the active energy ray-curable heat-expandable pressure-sensitive adhesive layer 1b of the dicing die-bonding film 10 shown in FIG. 1, the part 1bB formed of a non-cured active energy ray-curable heat-expandable pressure-sensitive adhesive sticks to the die-bonding film 3, and the holding power when dicing can be secured. In such a way, the active energy ray-curable heat-expandable pressure-sensitive adhesive can support the die-bonding film 3 for fixing the semiconductor chip onto an adherend such as a substrate with a good balance between adhesion and peeling. In the active energy ray-curable heat-expandable pressure-sensitive adhesive layer 1b of the dicing die-bonding film 11 shown in FIG. 2, the part corresponding to the above-mentioned part 1bB can fix a dicing ring. The dicing ring made of e.g., a metal such as stainless steel or a resin can be used.

Moreover, by applying a prescribed heat treatment to the active energy ray-curable heat-expandable pressure-sensitive adhesive layer, a shape change of the active energy ray-curable heat-expandable pressure-sensitive adhesive layer is generated and pressure-sensitive adhesive force between the active energy ray-curable heat-expandable pressure-sensitive adhesive layer and the die-bonding film is remarkably decreased, whereby the pressure-sensitive adhesive force can be decreased to almost zero and excellent pick-up properties can be imparted.

As the active energy ray-curable heat-expandable pressure-sensitive adhesive for forming the active energy ray-curable heat-expandable pressure-sensitive adhesive layer, an active energy ray-curable heat-expandable pressure-sensitive adhesive containing an active energy ray-curable pressure-sensitive adhesive and a foaming agent can be used. In the invention, as the active energy ray-curable pressure-sensitive adhesive, an active energy ray-curable pressure-sensitive adhesive containing the following acrylic polymer A can be suitably used. Therefore, as the active energy ray-curable heat-expandable pressure-sensitive adhesive, an active energy ray-curable heat-expandable pressure-sensitive adhesive containing the following acrylic polymer A can be suitably used.

Acrylic polymer A: an acrylic polymer having a constitution that a polymer composed of a monomer composition containing 50% by weight or more of an acrylic acid ester represented by CH₂═CHCOOR (in which R is an alkyl group having 6 to 10 carbon atoms) and 10% by weight to 30% by weight of a hydroxyl group-containing monomer and containing no carboxyl group-containing monomer is addition reacted with an isocyanate compound having a radical-reactive carbon-carbon double bond in an amount of 50 mol % to 95 mol % based on the hydroxyl group-containing monomer.

As the active energy ray-curable pressure-sensitive adhesive (or active energy ray-curable heat-expandable pressure-sensitive adhesive), an active energy ray-curable pressure-sensitive adhesive (or active energy ray-curable heat-expandable pressure-sensitive adhesive) containing an acrylic polymer as the base polymer can be suitably used. Examples of the acrylic polymer include those in which an acrylic acid ester is used as a main monomer component. Examples of the acrylic acid esters include alkyl acrylates, acrylic acid esters having an aromatic ring (aryl acrylates such as phenyl acrylate, etc.), and acrylic acid esters having an alicyclic hydrocarbon group (cycloalkyl acrylates such as cyclopentyl acrylate and cyclohexyl acrylate, isobornyl acrylate, etc.). Alkyl acrylates and cycloalkyl acrylates are suitable and particularly, alkyl acrylates can be suitably used. The acrylic acid esters can be used alone or two or more types may be used in combination.

Examples of the alkyl acrylates include alkyl acrylates having an alkyl group containing 1 to 30 carbon atoms (particularly, alkyl acrylates having an alkyl group containing 4 to 18 carbon atoms), such as methyl acrylate, ethyl acrylate, propyl acrylate, isopropyl acrylate, butyl acrylate, isobutyl acrylate, s-butyl acrylate, t-butyl acrylate, pentyl acrylate, isopentyl acrylate, hexyl acrylate, heptyl acrylate, octyl acrylate, isooctyl acrylate, 2-ethylhexyl acrylate, nonyl acrylate, isononyl acrylate, decyl acrylate, isodecyl acrylate, undecyl acrylate, dodecyl acrylate, tridecyl acrylate, tetradecyl acrylate, hexadecyl acrylate, octadecyl acrylate, and eicosyl acrylate. The alkyl acrylates may be any form of alkyl acrylates, such as straight chain alkyl acrylates or branched chain alkyl acrylates.

As described above, among the acrylic acid esters exemplified above, an alkyl acrylate represented by the chemical formula CH₂═CHCOOR (in which R is an alkyl group having 6 to 10 carbon atoms) (sometimes referred to as “C6-10 alkyl acrylate”) is preferably used in the present invention. When the number of carbon atoms of the alkyl acrylate is less than 6, the peeling force becomes too large and there is a case where the pick-up properties decrease. On the other hand, when the number of carbon atoms of the alkyl acrylate exceeds 10, the adhesiveness with the die-bonding film decreases, and as a result, there is a case where chip fly is generated when dicing. As the C6-10 alkyl acrylate, alkyl acrylates having an alkyl group containing 8 to 9 carbon atoms are particularly preferred. Of these, 2-ethylhexyl acrylate and isooctyl acrylate are most preferred.

Further, in the invention, the content of the C6-10 alkyl acrylate is preferably 50% by weight (wt %) or more and more preferably 70 to 90 wt %, based on the whole amount of the monomer components. When the content of the C6-10 alkyl acrylate is less than 50 wt %, the peeling force becomes too large, and there is a case where the pick-up properties decrease.

The acrylic polymer preferably contains a hydroxyl group-containing monomer copolymerizable with the above-mentioned acrylic acid ester. Examples of the hydroxyl group-containing monomer include 2-hydroxyethyl(meth)acrylate, 2-hydroxypropyl(meth)acrylate, 4-hydroxybutyl(meth)acrylate, 6-hydroxyhexyl (meth)acrylate, 8-hydroxyoctyl(meth)acrylate, 10-hydroxydecyl(meth)acrylate, 12-hydroxylauryl(meth)acrylate, and (4-hydroxymethylcyclohexyl)methyl(meth)acrylate. The hydroxyl group-containing monomer can be used alone or two or more types can be used in combination.

The content of the hydroxyl group-containing monomer is preferably in the range of 10 wt % to 30 wt %, and more preferably in the range of 15 wt % to 25 wt % based on the whole amount of the monomer components. When the content of the hydroxyl group-containing monomer is less than 10 wt % based on the whole amount of the monomer components, there is a case where the crosslinking after active energy ray irradiation becomes insufficient to cause decrease in pick-up properties or generation of adhesive residue on the semiconductor chip having the die-bonding film attached thereto. On the other hand, when the content of the hydroxyl group-containing monomer exceeds 30 wt % based on the whole amount of the monomer components, polarity of the pressure-sensitive adhesive becomes high and its interaction with the die-bonding film becomes high, so that the pick-up properties decrease.

The acrylic polymer may contain unit(s) corresponding to other monomer components copolymerizable with acrylic acid esters such as the alkyl acrylates according to needs for the purpose of modification of cohesion force, heat resistance, etc. Examples of such monomer components include methacrylic acid esters such as methyl methacrylate, ethyl methacrylate, propyl methacrylate, isopropyl methacrylate, butyl methacrylate, isobutyl methacrylate, s-butyl methacrylate, and t-butyl methacrylate; carboxyl group-containing monomers such as acrylic acid, methacrylic acid, carboxyethyl(meth)acrylate, carboxypentyl(meth)acrylate, itaconic acid, maleic acid, fumaric acid, and crotonic acid; acid anhydride monomers such as maleic anhydride and itaconic anhydride; sulfonic acid group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group-containing monomers such as 2-hydroxyethylacryloyl phosphate; styrene-based monomers such as styrene, vinyltoluene, and α-methylstyrene; olefins or dienes such as ethylene, butadiene, isoprene, and isobutyrene; halogen atom-containing monomers such as vinyl chloride; fluorine atom-containing monomers such as fluorinated (meth)acrylates; acrylamide; and acrylonitrile. One type or two types or more of these copolymerizable monomer components can be used. The amount of these copolymerizable monomers to be used is preferably 40 wt % or less of the whole amount of the monomer components. However, in the case of the carboxyl group-containing monomer, the adhesiveness between the active energy ray-curable heat-expandable pressure-sensitive adhesive layer and the die-bonding film becomes high through the reaction of the carboxyl group with the epoxy group in an epoxy resin in the die-bonding film, so that the peeling ability of both may decrease in some cases. Therefore, it is preferable to use no carboxyl group-containing monomer.

Moreover, the acrylic polymer preferably contains an isocyanate compound having a radical-reactive carbon-carbon double bond (sometimes referred to as “double bond-containing isocyanate compound”). Namely, the acrylic polymer preferably has a constitution that a double bond-containing isocyanate compound is incorporated into a polymer composed of a monomer composition containing the acrylic acid ester, the hydroxyl group-containing monomer, etc. through an addition reaction. Therefore, the acrylic polymer preferably has a radical-reactive carbon-carbon double bond in its molecular structure. Thereby, the polymer can form an active energy ray-curable heat-expandable pressure-sensitive adhesive layer (ultraviolet ray-curable heat-expandable pressure-sensitive adhesive layer, etc.) that is cured by active energy ray irradiation and thus the peeling force between the die-bonding film and the active energy ray-curable heat-expandable pressure-sensitive adhesive layer can be decreased.

Examples of the double bond-containing isocyanate compound include methacryloyl isocyanate, acryloyl isocyanate, 2-methacryloyloxyethyl isocyanate, 2-acryloyloxyethyl isocyanate, and m-isopropenyl-α,α-dimethylbenzyl isocyanate. The double bond-containing isocyanate compound can be used alone or two or more types can be used in combination.

The amount of the double bond-containing isocyanate compound to be used is preferably in the range of 50 to 95 mol %, and more preferably in the range of 75 to 90 mol % based on the hydroxyl group-containing monomer. When the amount of the double bond-containing isocyanate compound to be used is less than 50 mol % based on the hydroxyl group-containing monomer, there is a case where the crosslinking after active energy ray irradiation becomes insufficient to cause decrease in pick-up properties or generation of adhesive residue on the semiconductor chip having the die-bonding film attached thereto.

The acrylic polymer such as the acrylic polymer A can be obtained by polymerizing a single monomer or a monomer mixture of two or more types. The polymerization can be performed by any of methods such as solution polymerization (e.g., radical polymerization, anion polymerization, cation polymerization, etc.), emulsion polymerization, bulk polymerization, suspension polymerization, and photopolymerization (e.g., ultraviolet (UV) polymerization, etc.). From the viewpoint of preventing the contamination of a clean adherend, the content of low-molecular-weight substances is preferably small. From this viewpoint, the weight average molecular weight of the acrylic polymer is preferably 350,000 to 1,000,000, and more preferably about 450,000 to 800,000.

Moreover, in the active energy ray-curable pressure-sensitive adhesive (or active energy ray-curable heat-expandable pressure-sensitive adhesive), in order to control the pressure-sensitive adhesive force before the active energy ray irradiation and the pressure-sensitive adhesive force after the active energy ray irradiation, an external crosslinking agent can be optionally used. As a specific means for the external crosslinking method, there may be mentioned a method of adding and reacting a so-called crosslinking agent such as a polyisocyanate compound, an epoxy compound, an aziridine compound, or a melamine-based crosslinking agent. In the case where the external crosslinking agent is used, the amount is appropriately decided depending on the balance with the base polymer to be crosslinked and further the use application as a pressure-sensitive adhesive. The amount of the external crosslinking agent to be used is 20 parts by weight or less and preferably 0.1 part by weight to 10 parts by weight based on 100 parts by weight of the base polymer. Furthermore, the active energy ray-curable pressure-sensitive adhesive (or active energy ray-curable heat-expandable pressure-sensitive adhesive) may be mixed with conventionally known various additives such as tackifiers and antiaging agents.

Moreover, to the active energy ray-curable pressure-sensitive adhesive (or active energy ray-curable heat-expandable pressure-sensitive adhesive), an active energy ray-curable component (an active energy ray-curable monomer component, an active energy ray-curable oligomer component, etc.) may be added in order to control the pressure-sensitive adhesive force before the active energy ray irradiation and the like. Examples of the active energy ray-curable monomer component include urethane monomers, urethane (meth)acrylates, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butanediol di(meth)acrylate. Further, the active energy ray-curable oligomer component includes various types of oligomer components such as urethane-based, polyether-based, polyester-based, polycarbonate-based, and polybutadiene-based oligomers, and its molecular weight is appropriately in the range of about 100 to 30,000. The mixing amount of the active energy ray-curable monomer component or oligomer component can be appropriately determined depending on the type of the active energy ray-curable heat-expandable pressure-sensitive adhesive layer. Generally, the mixing amount of the active energy ray-curable monomer component or oligomer component is, for example, 500 parts by weight or less (e.g., 5 to 500 parts by weight, and preferably 40 to 150 parts by weight) based on 100 parts by weight of the base polymer constituting the active energy ray-curable pressure-sensitive adhesive or active energy ray-curable heat-expandable pressure-sensitive adhesive, such as the acrylic polymer.

Moreover, as the active energy ray-curable pressure-sensitive adhesive (or active energy ray-curable heat-expandable pressure-sensitive adhesive), besides the added type active energy ray-curable pressure-sensitive adhesive (or active energy ray-curable heat-expandable pressure-sensitive adhesive) described above, it is possible to use an internally provided type active energy ray-curable pressure-sensitive adhesive (or active energy ray-curable heat-expandable pressure-sensitive adhesive) using an acrylic polymer having a radical-reactive carbon-carbon double bond in the polymer side chain, in the main chain, or at the end of the main chain as the base polymer. The internally provided type active energy ray-curable pressure-sensitive adhesive (or active energy ray-curable heat-expandable pressure-sensitive adhesive) does not have to contain the oligomer component, etc. that is a low-molecular-weight component or does not contain a large amount thereof. Therefore, such a type of the pressure-sensitive adhesive is preferable because it can form an active energy ray-curable heat-expandable pressure-sensitive adhesive layer having a stable layer structure without migration of the oligomer component, etc. in the pressure-sensitive adhesive with time.

As the polymer having the radical-reactive carbon-carbon double bond, acrylic polymers having a radical-reactive carbon-carbon double bond in the molecule and having tackiness can be used without particular limitation. As basic skeletons of such acrylic polymers (the acrylic polymer A, etc.), the acrylic polymers exemplified above may be mentioned.

The method of introducing the radical-reactive carbon-carbon double bond into the acrylic polymer such as the acrylic polymer A is not particularly limited, and various methods can be adopted. However, from the viewpoint of a molecular design, it is easy to introduce the radical-reactive carbon-carbon double bond into the polymer side chain. For example, there may be mentioned a method including copolymerizing a monomer having a hydroxyl group with the acrylic polymer in advance and then performing a condensation or addition reaction of the polymer with an isocyanate compound having an isocyanate group that can react with the hydroxyl group and a radical-reactive carbon-carbon double bond while keeping the active energy ray curability of the radical-reactive carbon-carbon double bond. Examples of the isocyanate compound having an isocyanate group and a radical-reactive carbon-carbon double bond include those exemplified above. Further, as the acrylic polymer, there may be used a polymer in which, besides the hydroxyl group-containing monomer exemplified above, a hydroxyl group-containing ether-based compound such as 2-hydroxyethyl vinyl ether, 4-hydroxybutyl vinyl ether, or diethylene glycol monovinyl ether or the like is copolymerized, or the like.

In the internally provided type active energy ray-curable pressure-sensitive adhesive (or active energy ray-curable heat-expandable pressure-sensitive adhesive), a base polymer (particularly, an acrylic polymer) having the radical-reactive carbon-carbon double bond can be used alone. However, the active energy ray-curable monomer component or oligomer component can be also mixed to a level that does not deteriorate the characteristics. The amount of the active energy ray-curable oligomer component or the like is normally 50 parts by weight or less and preferably in the range of 0 to 30 parts by weight based on 100 parts by weight of the base polymer.

A photopolymerization initiator may be used in the active energy ray-curable pressure-sensitive adhesive (or active energy ray-curable heat-expandable pressure-sensitive adhesive) for the purpose of curing with an active energy ray. Examples of the photopolymerization initiator include α-ketol-based compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1-one; benzoin ether-based compounds such as benzoin ethyl ether, benzoin isopropyl ether, and anisoin methyl ether; ketal-based compounds such as benzyl dimethyl ketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds such as benzophenone, benzoylbenzoic acid and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphor quinone; halogenated ketones; acylphosphinoxides; and acylphosphonates. The mixing amount of the photopolymerization initiator is for example, 20 parts by weight or less (e.g., 0.05 to 20 parts by weight) based on 100 parts by weight of the base polymer that constitutes the pressure-sensitive adhesive, such as an acrylic polymer.

Moreover, examples of the active energy ray-curable pressure-sensitive adhesive include rubber-based pressure-sensitive adhesives and acryl-based pressure-sensitive adhesives containing an addition polymerizable compound having two or more unsaturated bonds, a photopolymerizable compound such as alkoxysilane having an epoxy group, and a photopolymerization initiator such as a carbonyl compound, an organic sulfur compound, a peroxide, an amine, and an onium salt-based compound, which are disclosed in JP-A-60-196956, herein incorporated by reference.

The gel fraction of the active energy ray-curable heat-expandable pressure-sensitive adhesive layer after active energy ray curing is preferably 90% by weight or more, and more preferably 94% by weight or more. When the gel fraction of the active energy ray-curable heat-expandable pressure-sensitive adhesive layer after active energy ray curing is less than 90% by weight, the pick-up properties may decrease and adhesive residue onto the semiconductor chip having the die-bonding film attached thereto may be generated in some cases. Incidentally, the gel fraction (% by weight) of the active energy ray-curable heat-expandable pressure-sensitive adhesive layer is a gel fraction according to the active energy ray-curable heat-expandable pressure-sensitive adhesive layer after active energy ray curing and before heat expansion.

The gel fraction of the active energy ray-curable heat-expandable pressure-sensitive adhesive layer can be measured by the following measurement method.

### Measurement Method of Gel Fraction

About 0.1 g was sampled from the active energy ray-curable heat-expandable pressure-sensitive adhesive layer subjected to ultraviolet ray irradiation (wavelength: 365 nm) at an ultraviolet ray irradiation integrated light intensity of 300 mJ/m² using an ultraviolet ray (UV) irradiation apparatus of a trade name “UM-810” manufactured by Nitto Seiki Co., Ltd. (but not subjected to a heat treatment for heat expansion) and was precisely weighed (sample weight). After wrapped with a mesh sheet, it was immersed in about 50 ml of ethyl acetate at room temperature for 1 week. Thereafter, a solvent-insoluble content (a content in the mesh sheet) was taken out of the ethyl acetate and dried at 80° C. for about 2 hours, the solvent-insoluble content was weighed (weight after immersion and drying), and a gel fraction (% by weight) was calculated according to the following equation (1).

Gel fraction(% by weight)={(Weight after immersion and drying)/(Sample weight)}×100 (1)

The active energy ray irradiation to the active energy ray-curable heat-expandable pressure-sensitive adhesive layer may be performed at any timing before through after the step of attaching the dicing film and the die-bonding film (before the attaching step, during the attaching step, or after the attaching step) or may be performed at any timing before through after the step of attaching the semiconductor wafer on the die-bonding film (before the attaching step, during the attaching step, or after the attaching step). Furthermore, the active energy ray irradiation to the active energy ray-curable heat-expandable pressure-sensitive adhesive layer may be performed at any timing before through after the heat expanding step of heat-expanding the active energy ray-curable heat-expandable pressure-sensitive layer (before the heat expanding step, during the heat expanding step, or after the heat expanding step). In the invention, from the viewpoint of the pick-up properties, it is preferable to perform the active energy ray irradiation before the heat expansion of the active energy ray-curable heat-expandable pressure-sensitive layer. Namely, it is suitable to heat the active energy ray-curable heat-expandable pressure-sensitive layer to effect heat expansion after the active energy ray curing by irradiating the active energy ray-curable heat-expandable pressure-sensitive adhesive layer with an active energy ray.

In the case where the active energy ray irradiation of the active energy ray-curable heat-expandable pressure-sensitive adhesive layer is performed before the above-mentioned dicing step (or during the dicing step), it is important to irradiate only the part corresponding to the semiconductor wafer attaching part through the die-bonding film with an active energy ray and not to irradiate the semiconductor wafer non-attaching part through the die-bonding film with the active energy ray. When the semiconductor wafer non-attaching part through the die-bonding film in the active energy ray-curable heat-expandable pressure-sensitive adhesive layer is not irradiated with the active energy ray as above, the part has a sufficient pressure-sensitive adhesive force, so that it can adhere to the die-bonding film, dicing ring, or the like to hold the semiconductor wafer effectively when the semiconductor wafer is diced in the dicing step. Of course, since the semiconductor wafer attaching part through the die-bonding film has been irradiated with the active energy ray, the part can exhibit a good peeling ability and the semiconductor chip can be easily picked up in the picking-up step.

On the other hand, in the case where the active energy ray-curable heat-expandable pressure-sensitive adhesive layer is irradiated with the active energy ray after the above dicing step, the part to be irradiated with the active energy ray may be a part including at least the semiconductor wafer attaching part through the die-bonding film and may be the whole surface.

It is important that the active energy ray-curable heat-expandable pressure-sensitive adhesive layer contains a foaming agent for imparting heat expandability. Accordingly, by heating the dicing die-bonding film at least partially at any time in the state that an adherend (particularly plural pieces of an adherend) is attached on the pressure-sensitive adhesive surface of the dicing die-bonding film through the die-bonding film to foam and/or expand the foaming agent contained in the heated part of the active energy ray-curable heat-expandable pressure-sensitive adhesive layer, the active energy ray-curable heat-expandable pressure-sensitive adhesive layer is at least partially expanded and, owing to this at least partial expansion of the active energy ray-curable heat-expandable pressure-sensitive adhesive layer, the pressure-sensitive adhesive surface of the active energy ray-curable heat-expandable pressure-sensitive adhesive layer corresponding to the expanded part is deformed unevenly to reduce the adhesion area between the pressure-sensitive adhesive surface of the active energy ray-curable heat-expandable pressure-sensitive adhesive layer and the die-bonding film on which the adherend has been attached. Consequently, the adhesive force between the pressure-sensitive adhesive surface of the active energy ray-curable heat-expandable pressure-sensitive adhesive layer deformed unevenly and the die-bonding film on which the adherend has been attached is decreased and thus the die-bonding film (die-bonding film having the adherend attached thereto) attached on the pressure-sensitive adhesive surface can be peeled from the dicing film. In the case where the active energy ray-curable heat-expandable pressure-sensitive adhesive layer is partially heated, the part to be partially heated may be a part containing at least the part on which the semiconductor chip to be peeled or picked up is attached through the die-bonding film.

The foaming agent used in the active energy ray-curable heat-expandable pressure-sensitive adhesive layer is not particularly limited and may be appropriately selected from known foaming agents. The foaming agent can be used alone or two or more types can be used in combination. As the foaming agent, a heat-expandable microsphere can be suitably used.

The heat-expandable microsphere is not particularly limited and can be appropriately selected from known heat-expandable microspheres (various inorganic heat-expandable microspheres, organic heat-expandable microspheres, etc.). As the heat-expandable microsphere, from the viewpoint of easy mixing operation and the like, a microcapsulated foaming agent can be suitably used. Examples of such a heat-expandable microsphere include microspheres in which a substance easily gasified and expanded, such as isobutane, propane, or pentane is included in a shell having elasticity. The above-mentioned shell is usually formed of a heat-meltable substance or a substance destroyed by heat expansion. Examples of the substance forming the shell include vinylidene chloride-acrylonitrile copolymer, polyvinyl alcohol, polyvinyl butyral, polymethyl methacrylate, polyacrylonitrile, polyvinylidene chloride, and polysulfone.

The heat-expandable microsphere can be produced by a commonly used method such as a coacervation method, an interfacial polymerization method, or the like. In this connection, as the heat-expandable microsphere, there can be used commercially available products, e.g., trade name “Matsumoto Microsphere” series manufactured by Matsumoto Yushi-Seiyaku Co., Ltd. such as trade name “Matsumoto Microsphere F30”, trade name “Matsumoto Microsphere F301D”, trade name “Matsumoto Microsphere F50D”, trade name “Matsumoto Microsphere F501D”, trade name “Matsumoto Microsphere F80SD”, and trade name “Matsumoto Microsphere F80VSD”, and also trade name “051DU”, trade name “053DU”, trade name “551DU”, trade name “551-20DU”, and trade name “551-80DU” manufactured by Expancel Company.

In the invention, as the foaming agent, a foaming agent other than the heat-expandable microsphere can be also used. As such a foaming agent, a foaming agent can be appropriately selected from various foaming agents such as various inorganic and organic foaming agents and used. Examples of representative inorganic foaming agents include ammonium carbonate, ammonium hydrogen carbonate, ammonium nitrite, sodium borohydride, and various azides.

Moreover, examples of representative organic foaming agents include water; chlorofluoroalkane-based compounds such as trichloromonofluoromethane and dichloromonofluoromethane; azo-based compounds such as azobisisobutyronitrile, azodicarbonamide, and barium azodicarboxylate; hydrazine-based compounds such as p-toluenesulfonylhydrazide, diphenylsulfone-3,3′-disulfonylhydrazide, 4,4′-oxybis(benzenesulfonylhydrazide), and allylbis(sulfonylhydrazide); semicarbazide-based compounds such as p-toluoylenesulfonylsemicarbazide and 4,4′-oxybis(benzenesulfonylsemicarbazide); triazole-based compounds such as 5-morpholinyl-1,2,3,4-thiatriazole; N-nitroso-based compounds such as N,N′-dinitrosopentamethyleneteloramine and N,N′-dimethyl-N,N′-dinitrosoterephthalamide.

In the invention, since the adhesive force of the active energy ray-curable heat-expandable pressure-sensitive adhesive layer is efficiently and stably reduced by heating treatment, a foaming agent having an appropriate strength which does not burst until the volume expanding ratio reaches 5 times or more, 7 times or more, particularly 10 times or more is preferable.

The mixing amount of the foaming agent (heat-expandable microsphere, etc.) may be appropriately set depending on the expanding magnitude and the reduction degree of adhesive force of the active energy ray-curable heat-expandable pressure-sensitive adhesive layer but in general, the amount is, for example, 1 part by weight to 150 parts by weight, preferably 10 parts by weight to 130 parts by weight, and further preferably 25 parts by weight to 100 parts by weight based on 100 parts by weight of the base polymer which forms the active energy ray-curable heat-expandable pressure-sensitive adhesive layer.

In the case where the heat-expandable microsphere is used as the foaming agent, the particle diameter (average particle diameter) of the heat-expandable microsphere can be appropriately selected depending on the thickness of the active energy ray-curable heat-expandable pressure-sensitive adhesive layer and the like. The average particle diameter of the heat-expandable microsphere can be, for example, selected from the range of 100 μm or less, preferably 80 μm or less, more preferably 1 μm to 50 μm, and particularly 1 μm to 30 μm. The particle diameter of the heat-expandable microsphere may be controlled in the process of forming the heat-expandable microsphere or may be controlled by means of classification or the like after the formation. The heat-expandable microsphere preferably has a uniform particle diameter.

In the invention, as the foaming agent, there is suitably used a foaming agent having a foaming starting temperature (heat expansion starting temperature, T₀) ranging from 80° C. to 210° C., preferably 95° C. to 200° C., and particularly preferably 100° C. to 170° C. When the foaming starting temperature of the foaming agent is lower than 80° C., the foaming agent may be foamed by the heat during the production of the dicing die-bonding film or during its use in some cases and thus handling properties and productivity decrease. On the other hand, when the foaming starting temperature of the foaming agent exceeds 210° C., excessive heat resistance is required for the base material of the dicing film and the die-bonding film and thus the case is not preferred in view of handling properties, productivity, and costs. Incidentally, the foaming starting temperature (T₀) of the foaming agent corresponds to the foaming starting temperature (T₀) of the active energy ray-curable heat-expandable pressure-sensitive adhesive layer.

As a method of foaming the foaming agent (i.e., a method of heat-expanding the active energy ray-curable heat-expandable pressure-sensitive adhesive layer), any method can be appropriately selected from known heating and foaming methods and adopted.

In the invention, the active energy ray-curable heat-expandable pressure-sensitive adhesive layer preferably has an elastic modulus in the form of containing no foaming agent of 5×10⁴ Pa to 1×10⁶ Pa, more preferably 5×10⁴ Pa to 8×10⁵ Pa, and particularly preferably 5×10⁴ Pa to 5×10⁵ Pa in the temperature range of 23° C. to 150° C., from the viewpoint of a balance between an appropriate adhesive force before heating treatment and a reduction degree in the adhesive force after heating treatment. When the elastic modulus (temperature: 23° C. to 150° C.) of the active energy ray-curable heat-expandable pressure-sensitive adhesive layer in the form of containing no foaming agent is less than 5×10⁴ Pa, the heat expandability becomes poor and the pick-up properties decrease in some cases. Moreover, when the elastic modulus (temperature: 23° C. to 150° C.) of the active energy ray-curable heat-expandable pressure-sensitive adhesive layer in the form of containing no foaming agent is more than 1×10⁶ Pa, the initial adhesiveness becomes poor in some cases. In this regard, the elastic modulus (Pa) of the active energy ray-curable heat-expandable pressure-sensitive adhesive layer is an elastic modulus with regard to the active energy ray-curable heat-expandable pressure-sensitive adhesive layer (containing no foaming agent) before the active energy ray curing.

The active energy ray-curable heat-expandable pressure-sensitive adhesive layer in the form of containing no foaming agent corresponds a pressure-sensitive adhesive layer (active energy ray-curable heat-expandable pressure-sensitive adhesive layer) formed of an active energy ray-curable pressure-sensitive adhesive (containing no foaming agent). Therefore, the elastic modulus of the active energy ray-curable heat-expandable pressure-sensitive adhesive layer in the form of containing no foaming agent can be measured using the active energy ray-curable pressure-sensitive adhesive (containing no foaming agent). In this connection, the active energy ray-curable heat-expandable pressure-sensitive adhesive layer can be formed from an active energy ray-curable heat-expandable pressure-sensitive adhesive containing a pressure-sensitive adhesive capable of forming a pressure-sensitive adhesive layer whose elastic modulus in the temperature range of 23° C. to 150° C. is 5×10⁴ Pa to 1×10⁶ Pa and a foaming agent.

The elastic modulus of the active energy ray-curable heat-expandable pressure-sensitive adhesive layer in the form of containing no foaming agent is determined as follows. An active energy ray-curable heat-expandable pressure-sensitive adhesive layer in the form where no foaming agent is added (i.e., an active energy ray-curable pressure-sensitive adhesive layer formed of an active energy ray-curable pressure-sensitive adhesive containing no foaming agent) (sample) is produced. Then, the elastic modulus of the sample was measured in a shear mode under conditions of a frequency of 1 Hz, a temperature elevating rate of 5° C./minute, and a strain of 0.1% (23° C.) or 0.3% (150° C.) using a dynamic viscoelasticity measuring apparatus “ARES” manufactured by Rheometrics Co. Ltd. and is regarded as a value of shear storage elastic modulus G′ obtained at 23° C. or 150° C.

The elastic modulus of the active energy ray-curable heat-expandable pressure-sensitive adhesive layer can be controlled by adjusting the cured state by active energy ray curing, kind of the base polymer of the pressure-sensitive adhesive, crosslinking agent, additives, etc.

Moreover, in the invention, the active energy ray-curable heat-expandable pressure-sensitive adhesive layer preferably has a surface free energy of 30 mJ/m² or less (e.g., 1 mJ/m² to 30 mJ/m²) on the surface at a side where the die-bond film is formed, particularly the surface of the site coming into contact with the die-bonding film. The surface free energy of the active energy ray-curable heat-expandable pressure-sensitive adhesive layer is further preferably 15 mJ/m² to 30 mJ/m², and particularly preferably 20 mJ/m² to 28 mJ/m². In the case where the surface free energy of the active energy ray-curable heat-expandable pressure-sensitive adhesive layer exceeds 30 mJ/m², adhesiveness between the active energy ray-curable heat-expandable pressure-sensitive adhesive layer and the die-bonding film increases and the pick-up properties may decrease in some cases. In this connection, the surface free energy (mJ/m²) of the active energy ray-curable heat-expandable pressure-sensitive adhesive layer is surface free energy of the active energy ray-curable heat-expandable pressure-sensitive adhesive layer before the active energy ray curing and before the heat expansion.

In the invention, the surface free energy of the active energy ray-curable heat-expandable pressure-sensitive adhesive layer means a surface free energy value (γ_{S}) determined by measuring individual contact angles θ (rad) of water and methylene iodide against the surface of the active energy ray-curable heat-expandable pressure-sensitive adhesive layer and solving two equations as simultaneous linear equations obtained utilizing the measured values and values known from literatures as surface free energy values of the contact angle-measured liquids {water (dispersing component (γ_{L}^{d}): 21.8 (mJ/m²), polar component (γ_{L}^{p}): 51.0 (mJ/m²)), methylene iodide (dispersing component (γ_{L}^{d}): 49.5 (mJ/m²), polar component (γ_{L}^{p}): 1.3 (mJ/m²))} and the following equations (2a) to (2c).

γ_{S}=γ_{S}^{d}+γ_{S}^{p} (2a)

γ_{L}=γ_{L}^{d}+γ_{L}^{p} (2b)

(1+cos θ)γ_{L}=2(γ_{S}^{d}γ_{L}^{d})^{1/2}+2(γ_{S}^{p}γ_{L}^{p})^{1/2} (2c)

wherein respective symbols in the equations (2a) to (2c) are as follows, respectively.

θ: contact angle measured with a liquid drop of water or methylene iodide (rad)

γₛ: surface free energy of the pressure-sensitive layer (active energy ray-curable heat-expandable pressure-sensitive adhesive layer) (mJ/m²)

γ_{S}^{d}: dispersing component in surface free energy of the pressure-sensitive layer (active energy ray-curable heat-expandable pressure-sensitive adhesive layer) (mJ/m²)

γ_{S}^{d}: polar component in surface free energy of the pressure-sensitive layer (active energy ray-curable heat-expandable pressure-sensitive adhesive layer) (mJ/m²) γ_{L}: surface free energy of water or methylene iodide (mJ/m²) γ_{L}^{d}: dispersing component in surface free energy of water or methylene iodide (mJ/m²)

γ_{L}^{p}: polar component in surface free energy of water or methylene iodide (mJ/m²)

Moreover, the contact angle of water or methylene iodide against the surface of the active energy ray-curable heat-expandable pressure-sensitive adhesive layer was determined by dropping a liquid droplet of about 1 μL of water (distilled water) or methylene iodide onto the surface of the active energy ray-curable heat-expandable pressure-sensitive adhesive layer under the environment of the test place (temperature: 23±2° C., humidity: 50±5% RH) described in JIS Z 8703 and measuring the angle by three point method after 30 seconds of the dropping using a surface contact angle meter “CA-X” (manufactured by FACE Company).

The surface free energy of the active energy ray-curable heat-expandable pressure-sensitive adhesive layer can be controlled by adjusting the kind of the base polymer of the pressure-sensitive adhesive, additives, and the like.

The active energy ray-curable heat-expandable pressure-sensitive adhesive layer can be formed, for example, by mixing an active energy ray-curable pressure-sensitive adhesive, a foaming agent (heat-expandable microsphere, etc.), and optional solvent and other additives and shaping the mixture into a sheet-like layer utilizing a commonly used method. Specifically, the active energy ray-curable heat-expandable pressure-sensitive adhesive layer can be formed, for example, by a method including applying a mixture containing an active energy ray-curable pressure-sensitive adhesive, a foaming agent (heat-expandable microsphere, etc.), and optional solvent and other additives on a base material or a rubbery organic elastic intermediate layer to be mentioned below, a method including applying the above-mentioned mixture on an appropriate separator such as a releasing paper to form an active energy ray-curable heat-expandable pressure-sensitive adhesive layer and transferring (transcribing) it on a base material or a rubbery organic elastic intermediate layer, or the like method.

The thickness of the active energy ray-curable heat-expandable pressure-sensitive adhesive layer is not particularly limited and can be appropriately selected depending on a reduction degree of the adhesive force. For example, the thickness is about 5 μm to 300 μm, and preferably 20 μm to 150 μm. However, in the case where the heat-expandable microsphere is used as the foaming agent, it is important that the thickness of the active energy ray-curable heat-expandable pressure-sensitive adhesive layer is larger than the maximum particle diameter of the heat-expandable microsphere contained therein. When the thickness of the active energy ray-curable heat-expandable pressure-sensitive adhesive layer is too small, the surface smoothness is impaired due to the unevenness of the heat-expandable microsphere and thus the adhesiveness before heating (non-foaming state) decreases. In addition, the deformation degree of the active energy ray-curable heat-expandable pressure-sensitive adhesive layer by the heating treatment is little and thus it is difficult to smoothly reduce the adhesive force. On the other hand, when the thickness of the active energy ray-curable heat-expandable pressure-sensitive adhesive layer is too large, cohesion failure tends to occur in the active energy ray-curable heat-expandable pressure-sensitive adhesive layer after expansion or foaming by the heating treatment and adhesive residue may be generated on the adherend in some cases.

The active energy ray-curable heat-expandable pressure-sensitive adhesive layer may be either a single layer or a multi layer.

In the invention, the active energy ray-curable heat-expandable pressure-sensitive adhesive layer may contain various additives (e.g., colorants, thickeners, extenders, fillers, tackifiers, plasticizers, antiaging agents, antioxidants, surfactants, crosslinking agents, etc.) within the range where the advantages and the like of the invention are not impaired.

The active energy ray-curable heat-expandable pressure-sensitive adhesive layer can be cured by irradiation with an active energy ray. As such an active energy ray, there may be, for example, mentioned ionizing radiations such as α ray, β ray, γ ray, neutron beam, and electron beam and ultraviolet rays. Particularly, ultraviolet rays are suitable. Irradiation energy, irradiation time, and irradiation method when the active energy ray is irradiated are not particularly limited and are suitably selected so as to be able to activate a photopolymerization initiator to cause a curing reaction. In the case where ultraviolet rays are adopted as the active energy ray, as ultraviolet irradiation, for example, irradiation of ultraviolet rays whose luminance at a wavelength of 300 nm to 400 nm is 1 mW/cm² to 200 mW/cm² is performed at a light intensity of about 400 mJ/cm² to 4000 mJ/cm². Moreover, as a light source of the ultraviolet rays, those having a spectral distribution in the wavelength region of 180 nm to 460 nm, preferably 300 nm to 400 nm are used. For example, an irradiation apparatus such as chemical lamp, black light, mercury arc, low-pressure mercury lamp, medium-pressure mercury lamp, high-pressure mercury lamp, ultrahigh-pressure mercury lamp, metal halide lamp, or the like can be used. In this connection, as the light source of ultraviolet rays, an irradiation apparatus capable of generating an ionizing radiation having a longer or shorter wavelength than the above wavelength may be used.

In the invention, the active energy ray-curable heat-expandable pressure-sensitive adhesive layer can be heat-expanded by heating. The heating treatment can be performed utilizing an appropriate heating means such as a hot plate, a hot-air drier, a near-infrared lamp, or an air drier. The heating temperature at the heating treatment may be the foaming starting temperature (heat expansion starting temperature) of the foaming agent (heat-expandable microsphere, etc.) in the active energy ray-curable heat-expandable pressure-sensitive adhesive layer or higher. The conditions for the heating treatment can be appropriately set depending on a decreasing profile of the adhesion area by the kind and the like of the foaming agent (heat-expandable microsphere, etc.), heat resistance of the base material, the die-bonding film, etc., heating methods (heat capacity, heating means, etc.), and the like. General conditions for the heating treatment are as follows: temperature of 100° C. to 250° C. for 1 second to 90 seconds (hot plate and the like) or 5 minutes to 15 minutes (hot-air drier and the like). The heating treatment can be performed at an appropriate stage depending on the intended purpose of use. Moreover, there are cases where an infrared lamp or heated water can be used as a heat source at the heating treatment.

(Intermediate Layer)

In the invention, an intermediate layer may be provided between the base material and the active energy ray-curable heat-expandable pressure-sensitive adhesive layer. As such an intermediate layer, there may be mentioned a coating layer of an undercoating agent for the purpose of improving the adhesive force. In addition, examples of the intermediate layer other than the coating layer of an undercoating agent include a layer for the purpose of imparting good deformation properties, a layer for the purpose of increasing the adhesion area to the adherend (semiconductor wafer, etc.), a layer for the purpose of improving the adhesive force, a layer for the purpose of achieving a good following ability to the surface shape of the adherend (semiconductor wafer, etc.), a layer for the purpose of improving processing ability for reducing the adhesive force by heating, and a layer for the purpose of improving the peeling ability from the adherend (semiconductor wafer, etc.) after heating.

Particularly, from the viewpoints of imparting the deformation properties to the dicing film having the active energy ray-curable heat-expandable pressure-sensitive adhesive layer and improving the peeling ability thereof after heating, it is preferable to provide a rubbery organic elastic intermediate layer between the base material and the active energy ray-curable heat-expandable pressure-sensitive adhesive layer. As above, by providing the rubbery organic elastic intermediate layer, the surface of the dicing die-bonding film can be well followed to the surface shape of the adherend at the time of adhering the dicing die-bonding film to the adherend, whereby the adhesion area can be enlarged. In addition, the heat expansion of the active energy ray-curable heat-expandable pressure-sensitive adhesive layer can be highly (accurately) controlled at the time of heating and peeling the die-bonding film with the adherend from the dicing film, whereby the active energy ray-curable heat-expandable pressure-sensitive adhesive layer can be expanded preferentially and uniformly in a thickness direction. Namely, the rubbery organic elastic intermediate layer can play an action to provide a large adhesion area by following the surface to the surface shape of the adherend when the dicing die-bonding film is adhered to the adherend and an action to facilitate the formation of a waving structure through three-dimensional structural change of the active energy ray-curable heat-expandable pressure-sensitive adhesive layer by reducing the restriction of foaming and/or expansion in a plane direction of the dicing film when the active energy ray-curable heat-expandable pressure-sensitive adhesive layer is foamed and/or expanded by heating for the purpose of peeling the die-bonding film with the adherend from the dicing film.

Incidentally, the rubbery organic elastic intermediate layer is a layer provided according to needs as mentioned above and may not necessarily be provided. The rubbery organic elastic intermediate layer is preferably provided for the purpose of enhancing the fixing ability of the adherend during processing and the peeling ability thereof after heating.

The rubbery organic elastic intermediate layer is preferably provided on the surface of the active energy ray-curable heat-expandable pressure-sensitive adhesive layer at the base material side in the form overlaid on the active energy ray-curable heat-expandable pressure-sensitive adhesive layer. In this connection, the intermediate layer can also be provided as a layer other than the intermediate layer between the base material and the active energy ray-curable heat-expandable pressure-sensitive adhesive layer.

The rubbery organic elastic intermediate layer can be interposed on one surface or both surfaces of the base material.

The rubbery organic elastic intermediate layer is preferably formed of a natural rubber, a synthetic rubber, or a synthetic resin having rubber elasticity, for example, which has a D-type Shore hardness in accordance with ASTM D-2240 of 50 or less, particularly 40 or less. In this connection, even when a polymer is an essentially hard polymer such as polyvinyl chloride, rubber elasticity can be exhibited in combination with a blending agent such as a plasticizer or a softener. Such a composition can be also used as a constitutional material of the rubbery organic elastic intermediate layer.

The rubbery organic elastic intermediate layer can be formed by a formation method such as a method including applying a coating liquid containing a rubbery organic elastic layer-forming material such as the natural rubber, synthetic rubber, or synthetic resin having rubber elasticity (coating method), a method including adhering onto the base material a film composed of the rubbery organic elastic layer-forming material or a laminate film in which a layer composed of the rubbery organic elastic intermediate layer-constituting material is formed on one or more active energy ray-curable heat-expandable pressure-sensitive adhesive layers in advance (dry laminate method), or a method including co-extruding a resin composition containing a constitutional material of the base material and a resin composition containing the rubbery organic elastic layer-forming material (co-extrusion method).

Incidentally, the rubbery organic elastic intermediate layer may be formed of a pressure-sensitive adhesive substance containing a natural rubber, a synthetic rubber, or a synthetic resin having rubber elasticity as a main component and may be formed of a foamed film mainly containing such a component. The foaming can be achieved by a commonly used method, e.g., a method by mechanical stirring, a method utilizing a reaction-formed gas, a method using a foaming agent, a method removing a soluble substance, a method by spraying, a method of forming a syntactic foam, a sintering method, or the like.

The thickness of the intermediate layer such as the rubbery organic elastic intermediate layer is, for example, about 5 μm to 300 μm, and preferably about 20 μm to 150 μm. In the case where the intermediate layer is, for example, a rubbery organic elastic intermediate layer, when the thickness of the rubbery organic elastic intermediate layer is too small, the three-dimensional structural change after heat foaming cannot be achieved and thus the peeling ability becomes worse in some cases.

The intermediate layer such as the rubbery organic elastic intermediate layer may be a single layer or may be constituted by two or more layers. Moreover, as the intermediate layer such as the rubbery organic elastic intermediate layer, it is preferable to use a layer which does not inhibit transmittance of the active energy ray.

Incidentally, the intermediate layer may contain various additives (e.g., colorants, thickeners, extenders, fillers, tackifiers, plasticizers, antiaging agents, antioxidants, surfactants, crosslinking agents, etc.) within the range where the advantages and the like of the invention are not impaired.

### (Die-Bonding Film)

It is important that the die-bonding film has a function of adhering and supporting a semiconductor wafer during processing of the semiconductor wafer (e.g., cutting thereof into a chip form) which is press boned on the die-bonding film and a function of acting as a bonding layer of the processed body of the semiconductor wafer (e.g., a semiconductor chip cut into a chip form) with various carriers when the processed body of the semiconductor wafer is mounted. Particularly, as the die-bonding film, it is important to have such adhesiveness that cut pieces do not fly during processing of the semiconductor wafer (e.g., processing such as cutting).

In the invention, the die-bonding film is constituted by a resin composition containing an epoxy resin. In the resin composition, the ratio of the epoxy resin can be appropriately selected from the range of 5% by weight or more, preferably 7% by weight or more, and more preferably 9% by weight or more based on the whole amount of the polymer components. The upper limit of ratio of the epoxy resin is not particularly limited and may be 100% by weight or less, but it is preferably 50% by weight or less, and more preferably 40% by weight or less based on the whole amount of the polymer components.

The epoxy resin is preferable from the viewpoint of containing fewer ionic impurities and the like that corrode a semiconductor element. The epoxy resin is not particularly limited as long as it is generally used as an adhesive composition. For example, a difunctional epoxy resin or a polyfunctional epoxy resin such as a bispehnol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a biphenyl type epoxy resin, a naphthalene type epoxy resin, a fluorene type epoxy resin, a phenol novolak type epoxy resin, an o-cresol novolak type epoxy resin, a trishydroxyphenylmethane type epoxy resin, and a tetraphenylolethane type epoxy resin or an epoxy resin such as a hydantoin type epoxy resin, a trisglycidylisocyanurate type epoxy resin or a glycidylamine type epoxy resin may be used. The epoxy resins can be used alone or two or more types can be used in combination.

As the epoxy resin, among those exemplified above, a novolak type epoxy resin, a biphenyl type epoxy resin, a trishydroxyphenylmethane type epoxy resin, and a tetraphenylolethane type epoxy resin are particularly preferable. This is because these epoxy resins have high reactivity with a phenol resin as a curing agent and are superior in heat resistance and the like.

Moreover, other thermosetting resins or thermoplastic resins can be used in combination in the die-bonding film according to needs. Examples of the thermosetting resin include phenol resins, amino resins, unsaturated polyester resins, polyurethane resins, silicone resins, and thermosetting polyimide resins. These thermosetting resins can be used alone or two or more types can be used in combination. Further, the phenol resin is preferable as the curing agent of the epoxy resin.

Furthermore, the phenol resin acts as a curing agent of the epoxy resin, and examples thereof include novolak type phenol resins such as phenol novolak resins, phenol aralkyl resins, cresol novolak resins, tert-butylphenol novolak resins, and nonylphenol novolak resins; resol type phenol resins; and polyoxystyrenes such as poly-p-oxystyrene. They can be used alone or two or more types can be used in combination. Among these phenol resins, phenol novolak resins and phenol aralkyl resins are particularly preferable. This is because connection reliability of the semiconductor device can be improved.

The mixing ratio of the epoxy resin to the phenol resin is preferably made, for example, such that the hydroxyl group in the phenol resin becomes 0.5 to 2.0 equivalents per equivalent of the epoxy group in the epoxy resin component. It is more preferably 0.8 to 1.2 equivalents. That is, when the mixing ratio becomes outside the range, a curing reaction does not proceed sufficiently, and the characteristics of the epoxy resin cured product tends to deteriorate.

Examples of the thermoplastic resin include natural rubber, butyl rubber, isoprene rubber, chloroprene rubber, ethylene-vinyl acetate copolymers, ethylene-acrylic acid copolymers, ethylene-acrylic acid ester copolymers, polybutadiene resin, polycarbonate resins, thermoplastic polyimide resins, polyamide resins such as 6-Nylon and 6,6-Nylon, phenoxy resins, acrylic resins, saturated polyester resins such as PET and PBT, polyamideimide resins, and fluorinated resins. These thermoplastic resins can be used alone or two type or more can be used in combination. Among these thermoplastic resins, acrylic resins in which the ionic impurities are less, the heat resistance is high, and reliability of the semiconductor element can be secured are particularly preferable.

The acrylic resins are not particularly limited, and examples thereof include polymers containing one type or two types or more of esters of acrylic acid or methacrylic acid having a straight chain or branched alkyl group having 30 or less carbon atoms, particularly 4 to 18 carbon atoms as component(s). Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (lauryl group), a tridecyl group, a tetradecyl group, a stearyl group, and an octadecyl group.

Moreover, other monomers for forming the acrylic resins (monomers other than the esters of acrylic acid or methacrylic acid having 30 or less carbon atoms) are not particularly limited, and examples thereof include carboxyl group-containing monomers such as acrylic acid, methacrylic acid, carboxylethyl acrylate, carboxylpentyl acrylate, itaconic acid, maleic acid, fumaric acid, and crotonic acid; acid anhydride monomers such as maleic anhydride and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl (meth)acrylate, 10-hydroxydecyl(meth)acrylate, 12-hydroxylauryl(meth)acrylate, and (4-hydroxymethylcyclohexyl)-methylacrylate; sulfonic acid-containing monomers such as styrenesulfonic acid, allylsulfonic acid, 2-(meth)acrylamido-2-methylpropanesulfonic acid, (meth)acrylamidopropanesulfonic acid, sulfopropyl(meth)acrylate, and (meth)acryloyloxynaphthalenesulfonic acid; and phosphoric acid-containing monomers such as 2-hydroxyethylacryloyl phosphate.

In the invention, the thermoplastic resin (particularly, an acrylic resin) can be used at a ratio of less than 90% by weight, e.g., 1% by weight to 90% by weight based on the whole amount of the polymer components. The ratio of the thermoplastic resin such as an acrylic resin is preferably 20% by weight to 85% by weight, and more preferably 40% by weight to 80% by weight based on the whole amount of the polymer components.

Because the adhesive layer (adhesive layer composed of a resin composition containing an epoxy resin) of the die-bonding film is crosslinked to some extent in advance, a polyfunctional compound that reacts with a functional group in the end of molecular chain of the polymer is preferably added as a crosslinking agent at the time of producing the adhesive layer. Accordingly, the adhesive characteristic under high temperature is improved, and the improvement of the heat resistance is attempted.

Here, other additives can be appropriately blended in the adhesive layer (adhesive layer composed of a resin composition containing an epoxy resin) of the die-bonding film according to needs. Examples of such additives include flame retardants, silane coupling agents, and ion trapping agents as well as colorants, extenders, fillers, antiaging agents, antioxidants, surfactants, crosslinking agents, etc. Examples of the flame retardants include antimony trioxide, antimony pentoxide, and brominated epoxy resins. The flame retardants can be used alone or two or more types can be used in combination. Examples of the silane coupling agents include β-(3,4-epoxycyclohexyl)ethyltrimethoxysilane, γ-glycidoxypropyltrimethoxysilane, and γ-glycidoxypropylmethyldiethoxysilane. The silane coupling agents can be used alone or two or more types can be used in combination. Examples of the ion trapping agents include hydrotalcites and bismuth hydroxide. The ion trapping agents can be used alone or two or more types can be used in combination.

The die-bonding film may be formed of a resin composition containing an epoxy resin and can have a configuration consisting of only a single layer of the adhesive layer (die adhesive layer) formed of a resin composition containing an epoxy resin), for example. Further, it may have a multi-layered structure of two layers or more by appropriately combining a thermoplastic resin having a different glass transition temperature and a thermosetting resin having a different heat curing temperature in addition to the epoxy resin.

Incidentally, because cutting water is used in the dicing step of the semiconductor wafer, there is a case where the die-bonding film absorbs moisture and the moisture content becomes a normal condition or more. When the die-bonding film is adhered to a substrate etc. with such high moisture content, there is a case where water vapor is accumulated on an adhering interface in the step of after-curing and floating is thus generated. Therefore, by making the die-bonding film have a configuration of sandwiching a core material having high moisture permeability with adhesive layers for die adhering, water vapor diffuses through the film in the step of after-curing and such a problem can be thus avoided. From such a viewpoint, the die-bonding film may have a multi-layered structure in which the adhesive layer is formed on one face or both faces of the core material.

Examples of the core material include films (e.g., polyimide films, polyester films, polyethylene terephthalate films, polyethylene naphthalate films, polycarbonate films, etc.), resin substrates reinforced with a glass fiber or a plastic nonwoven fiber, a silicon substrates, and glass substrates.

The die-bonding film preferably has an elastic modulus (particularly, an elastic modulus of the adhesive layer formed of a resin composition containing an epoxy resin) in the temperature range of T₀ to T₀+20° C. of 1×10⁵ Pa to 1×10¹⁰ Pa, in which T₀ represents the foaming starting temperature (° C.) of the active energy ray-curable heat-expandable pressure-sensitive adhesive layer of the dicing film. It is more preferable that the elastic modulus of the die-bonding film (particularly, the elastic modulus of the adhesive layer formed of a resin composition containing an epoxy resin) in a temperature range of T₀ to T₀+20° C. is more preferably 1×10⁵ Pa to 1×10⁸ Pa, and particularly preferably 1×10⁵ Pa to 1×10⁷ Pa. In the case where the elastic modulus of the die-bonding film (particularly, the adhesive layer) (temperature: T₀ to T₀+20° C.) is less than 1×10⁵ Pa, at the time when the active energy ray-curable heat-expandable pressure-sensitive adhesive layer is foamed and peeled by heating treatment, the die-bonding film may follow the surface shape change of the pressure-sensitive adhesive by heat expansion and thus the decrease in peeling strength may be inhibited in some cases. Incidentally, the elastic modulus (Pa) of the die-bonding film is elastic modulus of the die-bonding film before adhesive force is exhibited by heat curing.

The elastic modulus of the die-bonding film is determined by preparing a die-bonding film without laminating the die-bonding film onto the dicing film and measuring elastic modulus in a tensile mode under conditions of a sample width of 10 mm, a sample length of 22.5 mm, a sample thickness of 0.2 mm, a frequency of 1 Hz, and a temperature elevating rate of 10° C./minute under a nitrogen atmosphere at a prescribed temperature (T₀° C., (T₀+20)° C.) using a dynamic viscoelasticity measuring apparatus “Solid Analyzer RS A2” manufactured by Rheometrics Co. Ltd. and is regarded as a value of tensile storage elastic modulus E′ obtained.

Incidentally, the foaming starting temperature (T₀) of the active energy ray-curable heat-expandable pressure-sensitive adhesive layer means minimum heating treatment temperature capable of reducing the adhesive force of the active energy ray-curable heat-expandable pressure-sensitive adhesive layer containing the foaming agent (heat-expandable microsphere etc.) to 10% or less of the adhesive force before heating, by heating treatment.

Therefore, the foaming starting temperature can be determined by measuring the minimum heating treatment temperature capable of reducing the adhesive force (pressure-sensitive adhesive force) of the active energy ray-curable heat-expandable pressure-sensitive adhesive layer containing the foaming agent (heat-expandable microsphere etc.) to 10% or less of the adhesive force before heating. Specifically, a polyethylene terephthalate film (trade name “Lumilar S10#25” (manufactured by Toray Industries, Inc.); sometimes referred to as “PET film”) having a width of 20 mm and a thickness of 25 μm is attached on the surface of the active energy ray-curable heat-expandable pressure-sensitive adhesive layer containing the foaming agent (heat-expandable microsphere, etc.) of the dicing film by means of a hand roller so as not to entrain air bubbles, to thereby prepare a test piece. With regard to the test piece, the PET film is peeled off at a peeling angle of 180° after 30 minutes of the attaching of the PET film, the pressure-sensitive adhesive force at that time (measuring temperature: 23° C., drawing rate: 300 mm/min, peeling angle: 180°) is then measured, and this pressure-sensitive adhesive force is regarded as “initial pressure-sensitive adhesive force”. Moreover, the test piece produced by the above-mentioned method is placed in a heat-cycling drier set to each temperature (heating treatment temperature) for 1 minute and then taken out of the heat-cycling drier, followed by leaving it to stand at 23° C. for 2 hours. Thereafter, the PET film is peeled off at a peeling angle of 180°, the pressure-sensitive adhesive force at that time (measuring temperature: 23° C., drawing rate: 300 mm/min, peeling angle: 180°) is then measured, and this pressure-sensitive adhesive force is regarded as “pressure-sensitive adhesive force after heating treatment”. Then, minimum heating treatment temperature at which the pressure-sensitive adhesive force after heating treatment becomes 10% or less of the initial pressure-sensitive adhesive force is regarded as the foaming starting temperature (T₀).

Here, the elastic modulus of the die-bonding film can be controlled by adjusting the kind and the state of crosslinking or curing of the die-bonding film or the base polymer of the pressure-sensitive adhesive layer.

The thickness of the die-bonding film is not particularly limited. However, it is about 5 μm to 100 μm, and preferably about 5 μm to 50 μm.

The die-bonding film of the dicing die-bonding film is preferably protected by a separator (not shown in Figures). The separator has a function as a protecting material that protects the die-bonding film until it is practically used. Further, the separator can be used as a supporting base material when transferring the die-bonding film to the active energy ray-curable heat-expandable pressure-sensitive adhesive layer. The separator is peeled when attaching a workpiece onto the die-bonding film of the dicing die-bonding film. As the separator, a film of polyethylene or polypropylene, as well as a plastic film (polyethylene telephthalate) or a paper whose surface is coated with a releasing agent such as a fluorine-based releasing agent or a long-chain alkyl acrylate-based releasing agent can also be used. The separator can be formed by a conventionally known method. Moreover, the thickness or the like of the separator is not particularly limited.

According to the invention, the dicing die-bonding film can be made to have an antistatic function. Owing to the antistatic function, the circuit can be prevented from breaking down due to the generation of electrostatic energy at the time of adhesion and peeling of the dicing die-bonding film or charging of a workpiece (a semiconductor wafer, etc.) by the electrostatic energy. Imparting of the antistatic function can be performed by an appropriate manner such as a method of adding an antistatic agent or a conductive substance to the base material, the active energy ray-curable heat-expandable pressure-sensitive adhesive layer, and the die-bonding film or a method of providing a conductive layer composed of a charge-transfer complex, a metal film, or the like onto the base material. As these methods, a method in which an impurity ion having a fear of changing quality of the semiconductor wafer is difficult to generate is preferable. Examples of the conductive substance (conductive filler) to be blended for the purpose of imparting conductivity, improving heat conductivity, and the like include a sphere-shaped, a needle-shaped, a flake-shaped metal powder such as silver, aluminum, gold, copper, nickel, and a conductive alloy; a metal oxide such as alumina; amorphous carbon black, and graphite. However, the die-bonding film is preferably non-conductive from the viewpoint of having no electric leakage.

The dicing die-bonding film of the invention can have an appropriate form such as a sheet form or a tape form.

### (Producing Method of Dicing Die-Bonding Film)

The producing method of the dicing die-bonding film of the invention is described with the dicing die-bonding film 10 as an example. First, the base material 1a can be formed by a conventionally known film producing method. Examples of the film-forming method include a calendar film-forming method, a casting method in an organic solvent, an inflation extrusion method in a closely sealed system, a T-die extrusion method, a co-extrusion method, and a dry laminating method.

Next, the active energy ray-curable heat-expandable pressure-sensitive adhesive layer 1b is formed by applying an active energy ray-curable heat-expandable pressure-sensitive adhesive composition containing the heat-expandable pressure-sensitive adhesive on the base material 1a, followed by drying (by crosslinking under heating according to needs). Examples of the application manner include roll coating, screen coating, and gravure coating. In this connection, the application of the active energy ray-curable heat-expandable pressure-sensitive adhesive composition may be performed directly onto the base material 1a to form the active energy ray-curable heat-expandable pressure-sensitive adhesive layer 1b on the base material 1a, or the active energy ray-curable heat-expandable pressure-sensitive adhesive composition may be applied onto a releasing paper or the like whose surface has been subjected to a releasing treatment and then transferred onto the base material 1a to form the active energy ray-curable heat-expandable pressure-sensitive adhesive layer 1b on the base material 1a.

On the other hand, an application layer is formed by applying a forming material for forming the die-bonding film 3 onto a releasing paper so as to have a prescribed thickness and further drying under prescribed conditions. The die-bonding film 3 is formed on the active energy ray-curable heat-expandable pressure-sensitive adhesive layer 1b by transferring this application layer onto the active energy ray-curable heat-expandable pressure-sensitive adhesive layer 1b. The die-bonding film 3 may also be formed on the active energy ray-curable heat-expandable pressure-sensitive adhesive layer 1b by directly applying the forming material for forming the die-bonding film 3 on the active energy ray-curable heat-expandable pressure-sensitive adhesive layer 1b, followed by drying under prescribed conditions. The dicing die-bonding film 10 according to the invention can be obtained as described above.

### (Semiconductor Wafer)

The semiconductor wafer is not particularly limited as long as it is a known or commonly used semiconductor wafer and can be appropriately selected from semiconductor wafers made of various materials. In the invention, as the semiconductor wafer, silicon wafer can be suitable used.

### (Producing Method of Semiconductor Device)

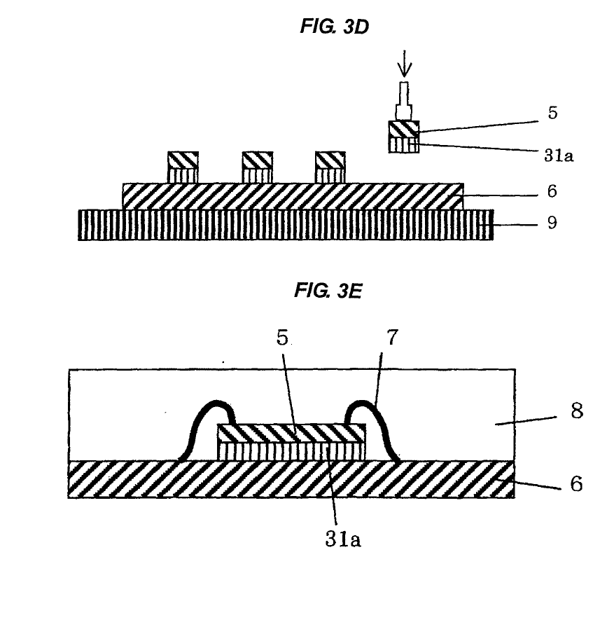

The process for producing a semiconductor device of the invention is not particularly limited as long as it is a process for producing a semiconductor device using the dicing die-bonding film. For example, a semiconductor device can be produced using the dicing die-bonding film of the invention as follows after the separator optionally provided on the die-bonding film is appropriate peeled. Hereinafter, referring to FIGS. 3A to 3E, the process is described while using the dicing die-bonding 11 as an example. First, a semiconductor wafer 4 is press-boned onto the die-bonding film 31 in the dicing die-bonding film 11 for fixing the semiconductor wafer by adhesion and holding (mounting step). The present step is performed while pressing with a pressing means such as a pressing roll.

Next, dicing of the semiconductor wafer 4 is performed. Consequently, the semiconductor wafer 4 is cut into a prescribed size and individualized (is formed into small pieces) to produce semiconductor chips 5. The dicing is performed following a normal method from the circuit face side of the semiconductor wafer 4, for example. Moreover, the present step can adopt, for example, a cutting method called full-cut that forms a slit reaching the dicing die-bonding film 11. The dicing apparatus used in the present step is not particularly limited, and a conventionally known apparatus can be used. Further, since the semiconductor wafer 4 is adhered and fixed by the dicing die-bonding film 11, chip crack and chip fly can be suppressed, as well as the damage of the semiconductor wafer can also be suppressed. In this connection, since the die-bonding film is formed of a resin composition containing an epoxy resin, even when it is cut by dicing, generation of adhesive extrusion from the adhesive layer of the die-bonding film is suppressed or prevented at the cut surface. As a result, re-attachment (blocking) of the cut surfaces themselves can be suppressed or prevented and thus the picking-up to be mentioned below can be furthermore conveniently performed.

In the case where the dicing die-bonding film is expanded, the expansion can be performed using a conventionally known expanding apparatus. The expanding apparatus has a doughnut-shaped outer ring capable of pushing the dicing die-bonding film downward through a dicing ring and an inner ring which has a diameter smaller than the outer ring and supports the dicing die-bonding film. Owing to the expanding step, it is possible to prevent the damage of adjacent semiconductor chips through contact with each other in the picking-up step to be mentioned below.

Picking-up of the semiconductor chip 5 is performed in order to collect a semiconductor chip that is adhered and fixed to the dicing die-bonding film 11. The method of picking-up is not particularly limited, and conventionally known various methods can be adopted. Examples thereof include a method including pushing up each semiconductor chip 5 from the base material 1a side of the dicing die-bonding film with a needle and picking-up the pushed semiconductor chip 5 with a picking-up apparatus.

Here, the picking-up is performed after curing the active energy ray-curable heat-expandable pressure-sensitive adhesive layer 1b by irradiating with an active energy ray as well as after heat-expanding the active energy ray-curable heat-expandable pressure-sensitive adhesive layer 1b by performing a prescribed heat treatment. Accordingly, the pressure-sensitive adhesive force (adhesive force) of the active energy ray-curable heat-expandable pressure-sensitive adhesive layer 1b to the die-bonding film 31 decreases, and the peeling of the semiconductor chip 5 becomes easy. As a result, the picking-up becomes possible without damaging the semiconductor chip 5. The conditions such as irradiation intensity and irradiation time at the active energy ray irradiation and heating temperature and heating treatment time at the heating treatment are not particularly limited, and they may be appropriately set according to needs. Moreover, curing of the active energy ray-curable heat-expandable pressure-sensitive adhesive layer by the active energy ray irradiation may be performed at any time before and after the heat expansion of the active energy ray-curable heat-expandable pressure-sensitive adhesive layer but, in view of the pick-up properties, it is preferable to achieve the heat expansion by the heating treatment after the curing through the irradiation with the active energy ray. Further, the irradiation apparatus usable for the active energy ray irradiation is not particularly limited and there may be mentioned the above-exemplified irradiation apparatus such as chemical lamp, black light, mercury arc, low-pressure mercury lamp, medium-pressure mercury lamp, high-pressure mercury lamp, ultrahigh-pressure mercury lamp, or metal halide lamp. The active energy ray curing of the active energy ray-curable heat-expandable pressure-sensitive adhesive layer by irradiation with the active energy ray may be performed at any time before the picking-up. Furthermore, the heating apparatus usable for the heating treatment is not particularly limited and there may be mentioned the above-exemplified heating apparatus such as a hot plate, a hot-air drier, a near-infrared lamp, or an air drier.

The semiconductor chip 5 picked up is adhered and fixed to an adherend 6 through the die-bonding film 31 interposed therebetween (die bonding). The adherend 6 is mounted onto a heat block 9. Examples of the adherend 6 include a lead frame, a TAB film, a substrate, and a semiconductor chip separately produced. The adherend 6 may be a deformable adherend that is easily deformed, or may be a non-deformable adherend (a semiconductor wafer, etc.) that is difficult to deform, for example.

A conventionally known substrate can be used as the substrate. Further, a metal lead frame such as a Cu lead frame and a 42 Alloy lead frame and an organic substrate composed of glass epoxy, BT (bismaleimide-triazine), or a polyimide can be used as the lead frame. However, the invention is not limited to the above, and includes a circuit substrate that can be used after mounting a semiconductor element and electrically connecting with the semiconductor element.

Since the die-bonding film 31 is formed of resin composition containing an epoxy resin, the adhesive force is enhanced by heat-curing and thus the semiconductor chip 5 can be adhered and fixed onto the adherend 6 to improve the heat resistance strength. Here, a product in which the semiconductor chip 5 is adhered and fixed onto a substrate or the like through the semiconductor wafer attaching part 31a can be subjected to a reflow step. Thereafter, wire bonding is performed by electrically connecting the tip of a terminal part (inner lead) of the substrate and an electrode pad (not shown in the figure) on the semiconductor chip 5 with a bonding wire 7, and furthermore, the semiconductor chip 5 is sealed with a sealing resin 8, followed by curing the sealing resin 8. Accordingly, the semiconductor device according to the present embodiment is manufactured.

### EXAMPLES

The following will illustratively describe preferred examples of the invention in detail. However, the materials, the mixing amount, and the like described in these examples are not intended to limit the scope of the invention to only those unless otherwise stated, and they are merely explanatory examples. Moreover, part in each example is a weight standard unless otherwise stated.

### Example 1

### Manufacture of Dicing Film

An acrylic polymer X was obtained by charging 95 parts of 2-ethylhexyl acrylate (hereinafter sometimes refers to as “2EHA”), 5 parts of 2-hydroxyethyl acrylate (hereinafter sometimes refers to as “HEA”), and 65 parts of toluene into a reactor equipped with a cooling pipe, a nitrogen introducing pipe, a thermometer, and a stirring apparatus, followed by performing a polymerization treatment at 61° C. for 6 hours in a nitrogen stream.

An acrylic polymer Y was obtained by adding 24.1 parts of 2-methacryloyloxyethyl isocyanate (sometimes referred to as “MOI”) (90 mol % based on HEA) to 100 parts of the acrylic polymer X, followed by performing an addition reaction treatment at 50° C. for 48 hours in an air stream.

Next, a pressure-sensitive adhesive solution of an active energy ray-curable pressure-sensitive adhesive was prepared by adding 3 parts of a polyisocyanate compound (trade name “COLONATE L” manufactured by Nippon Polyurethane Industry Co., Ltd.), 35 parts of a heat-expandable microsphere (trade name “Microsphere F-50D” manufactured by Matsumoto Yushi-Seiyaku Co., Ltd.; foaming starting temperature: 120° C.), and 5 parts of a photopolymerization initiator (trade name “IRUGACURE 651” manufactured by Ciba Specialty Chemicals) to 100 parts of the acrylic polymer Y.

An active energy ray-curable heat-expandable pressure-sensitive adhesive sheet (ultraviolet ray-curable heat-expandable pressure-sensitive adhesive sheet) as a dicing film was manufactured by applying the pressure-sensitive adhesive solution prepared above onto a polyethylene terephthalate film (PET film) having a thickness of 50 μm and performing heat-crosslinking at 80° C. for 3 minutes to form a pressure-sensitive adhesive layer (active energy ray-curable heat-expandable pressure-sensitive adhesive layer) having a thickness of 40 μm.

### <Manufacture of Die-Bonding Film>

59 parts of an epoxy resin 1 (trade name “EPICOAT 1004” manufactured by Japan Epoxy Resins (JER) Co., Ltd.), 53 parts of an epoxy resin 2 (trade name “EPICOAT 827” manufactured by Japan Epoxy Resins (JER) Co., Ltd.), 121 parts of a phenol resin (trade name “MILEX XLC-4L” manufactured by Mitsui Chemicals, Inc.), 222 parts of sphere silica (trade name “SO-25R” manufactured by Admatechs Co., Ltd.) based on 100 parts of an acrylic acid ester-based polymer (trade name “PARACRON W-197CM” manufactured by Negami Chemical Industrial Co., Ltd.) having ethyl acrylate-methyl methacrylate as the main component were dissolved into methyl ethyl ketone to prepare a solution of an adhesive composition having a solid concentration of 23.6% by weight.

The solution of the adhesive composition was applied onto a mold release-treated film composed of a PET film having a thickness of 38 μm on which a silicone mold release-treatment had been performed as a releasing liner (separator), and then dried at 130° C. for 2 minutes. Accordingly, a die-bonding film A having a thickness of 25 μm was manufactured. Furthermore, a dicing die-bonding film according to the present Example 1 was obtained by transferring the die-bonding film A onto the active energy ray-curable heat-expandable pressure-sensitive adhesive layer side of the dicing film described above.

### Example 2

### Manufacture of Die-Bonding Film

102 parts of an epoxy resin 1 (trade name “EPICOAT 1004” manufactured by Japan Epoxy Resins (JER) Co., Ltd.), 13 parts of an epoxy resin 2 (trade name “EPICOAT 827” manufactured by Japan Epoxy Resins (JER) Co., Ltd.), 119 parts of a phenol resin (trade name “MILEX XLC-4L” manufactured by Mitsui Chemicals, Inc.), 222 parts of sphere silica (trade name “SO-25R” manufactured by Admatechs Co., Ltd.) based on 100 parts of an acrylic acid ester-based polymer (trade name “PARACRON W-197CM” manufactured by Negami Chemical Industrial Co., Ltd.) having ethyl acrylate-methyl methacrylate as the main component were dissolved into methyl ethyl ketone to prepare a solution of an adhesive composition having a solid concentration of 23.6% by weight.

The solution of the adhesive composition was applied onto a mold release-treated film composed of a PET film having a thickness of 38 μm on which a silicone mold release-treatment had been performed as a releasing liner (separator), and then dried at 130° C. for 2 minutes. Accordingly, a die-bonding film B having a thickness of 25 μm was manufactured.

A dicing die-bonding film was manufactured in the same manner as in Example 1 except that the die-bonding film B was used instead of the die-bonding film A.

### Examples 3 to 7

A dicing die-bonding film was manufactured in each of Examples 3 to 7 in the same manner as in the Example 1 except that the dicing film was changed to a corresponding dicing film having the composition and the content shown in Table 1.

### Comparative Examples 1 and 2

A dicing die-bonding film was produced in each of Comparative Examples 1 and 2 in the same manner as in the Example 1 except that the dicing film was changed to a corresponding dicing film having the composition and the content shown in Table 1.

TABLE 1

| | | | | | | | | | Comparative | Comparative |
|---|---|---|---|---|---|---|---|---|---|---|
| | | Example 1 | Example 2 | Example 3 | Example 4 | Example 5 | Example 6 | Example 7 | Example 1 | Example 2 |
| Active energy ray- | 2EHA | 80 | 80 | 80 | 80 | 20 | 80 | 99 | 80 | 80 |
| curable heat-expandable | BA | — | — | — | — | 62 | — | — | — | — |
| pressure-sensitive | HEA | 20 | 20 | 20 | 20 | 18 | 17 | 1 | 20 | 20 |
| adhesive layer | AA | — | — | — | — | — | 3 | — | — | — |
| | MOI* | 24.1(90) | 24.1(90) | 8(30) | 24.1(90) | 21.6(90) | 20.4(90) | 1.2(90) | — | 24.1(90) |
| | C/L | 3 | 3 | 3 | 0.05 | 3 | 3 | 3 | 3 | 3 |
| | F-50D | 35 | 35 | 35 | 35 | 35 | 35 | 35 | 35 | — |
| | Irg651 | 5 | 5 | 5 | 5 | 5 | 5 | 5 | — | 5 |

| | | | | | | | | | |
|---|---|---|---|---|---|---|---|---|---|
| Die-bonding film | A | B | A | A | A | A | A | A | A |
| Surface free energy (mJ/m²) | 26.4 | 26.4 | 26.2 | 26.3 | 28.4 | 26.9 | 24.1 | 26.1 | 26.2 |
| Gel fraction after UV curing | 96 | 96 | 93 | 31 | 98 | 98 | 78 | 89 | 94 |
| (% by weight) | | | | | | | | | |
| G′(at 23° C.) (Pa) | 1.9 × 10⁵ | 1.9 × 10⁵ | 1.8 × 10⁵ | 8.5 × 10⁴ | 2.0 × 10⁵ | 2.0 × 10⁵ | 1.0 × 10⁵ | 1.9 × 10⁵ | 1.9 × 10⁵ |
| G′(at 150° C.) (Pa) | 1.8 × 10⁵ | 1.8 × 10⁵ | 1.6 × 10⁵ | 2.2 × 10⁴ | 1.9 × 10⁵ | 1.9 × 10⁵ | 8.8 × 10⁴ | 1.7 × 10⁵ | 1.8 × 10⁵ |
| E′(at T₀° C.) (Pa) | 1.4 × 10⁶ | <9 × 10⁴*2 | 1.4 × 10⁶ | 1.4 × 10⁶ | 1.4 × 10⁶ | 1.4 × 10⁶ | 1.4 × 10⁶ | 1.4 × 10⁶ | 1.4 × 10⁶ |
| E′(at T₀ + 20° C.) (Pa) | 1.2 × 10⁶ | <9 × 10⁴*2 | 1.2 × 10⁶ | 1.2 × 10⁶ | 1.2 × 10⁶ | 1.2 × 10⁶ | 1.2 × 10⁶ | 1.2 × 10⁶ | 1.2 × 10⁶ |
| Dicing properties | Good | Good | Good | Good | Good | Good | Good | Good | Good |
| Pick-up properties (%) | 100 | 74 | 99 | 81 | 69 | 63 | 78 | 32 | 0 |
| Fouling properties | 852 | 852 | 2435 | 1589 | 738 | 927 | 3850 | >30000 | 150 |

*The value in parenthesis represents mol % of MOI to HEA
*2E′ is too low to measure
T₀ = 120° C.

Here, meanings of the abbreviations described in Table 1 are as follows.

2EHA: 2-ethylhexyl acrylate
BA: n-butyl acrylate
AA: acrylic acid
HEA: 2-hydroxyethyl acrylate
MOI: 2-methacryloyloxyethyl isocyanate
C/L: a polyisocyanate compound (trade name “COLONATE L” manufactured by Nippon Polyurethane Industry Co., Ltd.)
Irg651: trade name “IRUGACURE 651” manufactured by Ciba Specialty Chemicals)
G′ (at 23° C.): elastic modulus of the pressure-sensitive adhesive layer in the dicing film at 23° C.
G′ (at 150° C.): elastic modulus of the pressure-sensitive adhesive layer in the dicing film at 150° C.
E′ (at T₀): elastic modulus of the die-bonding film at T₀
E′ (at T₀+20° C.): elastic modulus of the die-bonding film at T₀+20° C.

(Evaluation)

With regard to the dicing die-bonding films according to Examples 1 to 7 and Comparative Examples 1 and 2, the surface free energy of the pressure-sensitive adhesive layer in each dicing film, elastic modulus regarding the pressure-sensitive adhesive layer in each dicing film, elastic modulus of each die-bonding film, a gel fraction of the pressure-sensitive adhesive layer in each dicing film, dicing properties, pick-up properties, and fouling properties were evaluated or measured by the following evaluation or measurement methods. The results of the evaluation and measurement were also described in Table 1.

### <Evaluation Method of Surface Free Energy>

A contact angle θ (rad) was determined by dropping a liquid droplet of about 1 μL of water (distilled water) or methylene iodide onto the surface of the pressure-sensitive adhesive layer (the active energy ray-curable heat-expandable pressure-sensitive adhesive layer before active energy ray curing and before heat expansion in the case of the active energy ray-curable heat-expandable pressure-sensitive adhesive layer (Examples 1 to 7), the heat-expandable pressure-sensitive adhesive layer before heat expansion in the case of the heat-expandable pressure-sensitive adhesive layer (Comparative Example 1), or the active energy ray-curable pressure-sensitive adhesive layer before active energy ray curing in the case of the active energy ray-curable pressure-sensitive adhesive layer (Comparative Example 2)) in each dicing film, under the environment of the test place (temperature: 23±2° C., humidity: 50±5% RH) in accordance with JIS Z 8703 and measuring by three point method after 30 seconds of the dropping using a surface contact angle meter “CA-X” (manufactured by FACE Company). The surface free energy (γ_{S}) of the pressure-sensitive adhesive layer in the dicing film was calculated by solving two equations as simultaneous linear equations obtained utilizing the obtained two contact angles and values known from literatures as surface free energy values of water and methylene iodide and the following equations (2a) to (2c).

γ_{S}=γ_{S}^{d}+γ_{S}^{p} (2a)

γ_{L}=γ_{L}^{d}+γ_{L}^{p} (2b)

(1+cos θ)γ_{L}=2(γ_{S}^{d}γ_{L}^{d})^{1/2}+2(γ_{S}^{p}γ_{L}^{p})^{1/2} (2c)

Herein, respective symbols in the equations (2a) to (2c) are as follows, respectively.

θ: contact angle measured with a liquid drop of water or methylene iodide (rad)

γ_{S}: surface free energy of the pressure-sensitive layer (mJ/m²)

γ_{S}^{d}: dispersing component in surface free energy of the pressure-sensitive layer (mJ/m²)

γ_{S}^{p}: polar component in surface free energy of the pressure-sensitive layer (mJ/m²)

γ_{L}: surface free energy of water or methylene iodide (mJ/m²)

γ_{L}^{d}: dispersing component in surface free energy of water or methylene iodide (mJ/m²)

γ_{L}^{p}: polar component in surface free energy of water or methylene iodide (mJ/m²)

Value known as surface free energy value of water (distilled water): [dispersing component (γ_{L}^{d}): 21.8 (mJ/m²), polar component (γ_{L}^{p}): 51.0 (mJ/m²)]

Value known as surface free energy value of methylene iodide: [dispersing component (γ_{L}^{d}): 49.5 (mJ/m²), polar component (γ_{L}^{p}): 1.3 (mJ/m²)]

### <Measurement Method of Elastic Modulus of Pressure-Sensitive Adhesive Layer of Dicing Film>

The elastic modulus regarding the pressure-sensitive adhesive layer (active energy ray-curable heat-expandable pressure-sensitive adhesive layer) of the dicing film was evaluated or measured by preparing the same pressure-sensitive adhesive layer (sample) except that no foaming agent was contained. The elastic modulus was measured in a shear mode under conditions of a frequency of 1 Hz, a temperature elevating rate of 5° C./minute, and a strain of 0.1% (23° C.) or 0.3% (150° C.) using a dynamic viscoelasticity measuring apparatus “ARES” manufactured by Rheometrics Co. Ltd. and was regarded as a value of shear storage elastic modulus G′ obtained at 23° C. or 150° C.

### <Measurement Method of Elastic Modulus of Die-Bonding Film>

The elastic modulus of the die-bonding film was determined by preparing a die-bonding film without laminating the die-bonding film onto the dicing film and measuring elastic modulus in a tensile mode under conditions of a sample width of 10 mm, a sample length of 22.5 mm, a sample thickness of 0.2 mm, a frequency of 1 Hz, and a temperature elevating rate of 10° C./minute under a nitrogen atmosphere at a prescribed temperature (T₀, (T₀+20)° C.) using a dynamic viscoelasticity measuring apparatus “Solid Analyzer RS A2” manufactured by Rheometrics Co. Ltd. and was regarded as a value of tensile storage elastic modulus E′ obtained.

In this connection, T₀ was determined as follows.

A test piece was produced by attaching a PET film having a thickness of 25 μm on the surface of a pressure-sensitive adhesive layer (active energy ray-curable heat-expandable pressure-sensitive adhesive layer) of the dicing film by means of a hand roller so as not to entrain air bubbles. The PET film was peeled off at a peeling angle of 180° after 30 minutes of the attaching of the PET film, the pressure-sensitive adhesive force at that time (measuring temperature: 23° C., drawing rate: 300 mm/min, peeling angle: 180°) was then measured, and this pressure-sensitive adhesive force was regarded as “initial pressure-sensitive adhesive force”.

Moreover, the test piece prepared by the above-described method was placed in a heat-cycling drier set to each temperature (heating treatment temperature) for 1 minute and then taken out of the heat-cycling drier, followed by leaving it to stand at 23° C. for 2 hours. Thereafter, the PET film was peeled off at a peeling angle of 180°, the pressure-sensitive adhesive force at that time (measuring temperature: 23° C., drawing rate: 300 mm/min, peeling angle: 180°) was then measured, and this pressure-sensitive adhesive force was regarded as “pressure-sensitive adhesive force after heating treatment”.

Minimum heating treatment temperature at which the “pressure-sensitive adhesive force after heating treatment” decreases to 10% or less of the “initial pressure-sensitive adhesive force” was regarded as the foaming starting temperature (T₀).

The foaming starting temperature T₀ of the active energy ray-curable heat-expandable pressure-sensitive adhesive layer of each of the dicing films according to Examples 1 to 7 and Comparative Example 1 was 120° C. Since the pressure-sensitive adhesive layer of the dicing film according to Comparative Example 2 contained no foaming agent, the dicing film had no foaming starting temperature. However, in order to compare elastic modulus, the foaming starting temperature of the dicing film of Comparative Example 1 was regarded as 120° C. Therefore, in this case, T₀+20° C. was 140° C.

### <Measurement Method of Gel Fraction>

About 0.1 g was sampled from the active energy ray-curable heat-expandable pressure-sensitive adhesive layer subjected to ultraviolet ray irradiation (wavelength: 365 nm) at an ultraviolet ray irradiation integrated light intensity of 300 mJ/cm² using an ultraviolet ray (UV) irradiation apparatus of a trade name “UM-810” manufactured by Nitto Seiki Co., Ltd. and was precisely weighed (sample weight). After wrapped with a mesh sheet, it was immersed in about 50 ml of ethyl acetate at room temperature for 1 week. Thereafter, a solvent-insoluble content (a content in the mesh sheet) was taken out of the ethyl acetate and dried at 80° C. for about 2 hours. Subsequently, the solvent-insoluble content was weighed (weight after immersion and drying), and a gel fraction (% by weight) was calculated according to the following equation (1).

Gel fraction(% by weight)={(Weight after immersion and drying)/(Sample weight)}×100 (1)

### <Evaluation Method of Dicing Properties/Pick-Up Properties>

Using the dicing die-bonding film of each of Examples and Comparative Examples, the dicing properties was evaluated by actually dicing a semiconductor wafer and then peeling ability was evaluated, which are regarded as evaluation of dicing performance and picking-up performance of each dicing die-bonding film, respectively.

A semiconductor wafer (diameter of 8 inches, thickness of 0.6 mm; a silicon mirror wafer) was subjected to rear surface polishing treatment and a mirror wafer having a thickness of 0.025 mm was used as a workpiece. After the separator was peeled from the dicing die-bonding film, the mirror wafer (workpiece) was attached onto the die-bonding film by roller press-bonding at 40° C. and dicing was further performed. Herein, the dicing was performed as full cut so as to be a chip size of 10 mm square. In this connection, conditions for semiconductor wafer grinding, attaching conditions, and dicing conditions are as follows.

### (Conditions for Semiconductor Wafer Grinding)

Grinding apparatus: trade name “DFG-8560” manufactured by DISCO Corporation Semiconductor wafer: 8 inch diameter (rear surface was ground so as to be a thickness of 0.6 mm to 0.025 mm)

### (Attaching Conditions)

Attaching apparatus: trade name “MA-3000II” manufactured by Nitto Seiki Co., Ltd.
Attaching speed: 10 mm/min
Attaching pressure: 0.15 MPa
Stage temperature at the time of attaching: 40° C.

### (Dicing Conditions)

Dicing apparatus: trade name “DFD-6361” manufactured by DISCO Corporation
Dicing ring: “2-8-1” (manufactured by DISCO Corporation)
Dicing speed: 30 mm/sec
Dicing blade:

Z1; “NBC-ZH226J27HAAA” manufactured by DISCO Corporation

Dicing blade rotation speed:

Z1; 30,000 rpm

Cutting method: single step cutting
Wafer chip size: 10.0 mm square

In the dicing, it was confirmed whether the mirror wafer (workpiece) was firmly held on the dicing die-bonding film without peeling to effect the dicing satisfactory or not. The case where the dicing was well performed was ranked “Good” and the case where the dicing was not well performed was ranked “Poor”, thus the dicing ability being evaluated.

Then, using a trade name “UM-810” (manufactured by Nitto Seiki Co., Ltd.) as an ultraviolet ray (UV) irradiation apparatus, the dicing die-bonding film was irradiated with an ultraviolet ray (wavelength: 365 nm) at an ultraviolet irradiation integrated light quantity of 300 mJ/cm² from the PET film side.

Thereafter, each dicing die-bonding film was placed on a hot plate at T₀+20° C. (140° C. in Examples 1 to 7 and Comparative Examples 1 and 2) so that the surface of the dicing die-bonding film at the base material side came into contact with the surface of the hot plate and the pressure-sensitive adhesive layer (active energy ray-curable heat-expandable pressure-sensitive adhesive layer etc.) was subjected to a heating treatment for 1 minute. Then, the dicing die-bonding film was reversed so that the dicing die-bonding film was turned upside down in the air (so that the chips were put down) and the chips with the die-bonding film were peeled off by free falling. The peeling ratio (%) of the chips (total pieces: 400) on this occasion was determined to evaluate the pick-up properties. Therefore, the pick-up properties are better when the peeling ratio is closer to 100%.

### <Evaluation Method of Fouling Properties (Low Fouling Properties or Antifouling Properties)>

The separator of the dicing die-bonding film was peeled off in a clean room and the sheet piece was adhered to a 4 inches mirror wafer through the die-bonding film (pressure-sensitive adhesive layer). After allowed to stand at 23° C. for 1 hour, the sample was subjected to ultraviolet ray irradiation (wavelength: 365 nm) at an ultraviolet irradiation integrated light quantity of 300 mJ/cm² using a trade name “UM-810” (manufactured by Nitto Seiki Co., Ltd.) as an ultraviolet ray (UV) irradiation apparatus. Furthermore, each dicing die-bonding film was placed on a hot plate at T₀+20° C. (140° C. in Examples 1 to 7 and Comparative Examples 1 and 2) so that the base material of the dicing die-bonding film came into contact with the surface of the hot plate for 1 minute to perform a heating treatment to the active energy ray-curable heat-expandable pressure-sensitive adhesive layer of the dicing die-bonding film. Then, the sheet piece was peeled off at 23° C. at a peeling rate of 12 m/minute and a peeling angle of 180°. The number of particles having a size of 0.28 μm or more on the mirror wafer was counted by means of a trade name “SFS-6200” manufactured by KLA-Tencor Corporation to evaluate fouling properties (low fouling properties or antifouling properties). Therefore, the fouling properties are better as the value decreases.

As shown in Table 1, it was confirmed that the dicing die-bonding films according to Examples 1 to 7 were excellent in dicing ability and picking-up ability and the adherend such as a semiconductor wafer could be firmly held and dicing could be well performed. Moreover, it was confirmed that the adherend such as a semiconductor chip could be easily and well peeled and picked up with excellent low fouling properties (antifouling properties) by heat expansion under heating after curing with an active energy ray was performed by irradiation with an active energy ray such as ultraviolet rays.

While the present invention has been described in detail and with reference to specific embodiments thereof, it will be apparent to one skilled in the art that various changes and modifications can be made therein without departing from the scope thereof.

This application is based on Japanese patent application No. 2008-301559 filed Nov. 26, 2008, the entire contents thereof being hereby incorporated by reference.

What is claimed is:

1. A dicing die-bonding film comprising:
a dicing film having a pressure-sensitive adhesive layer provided on a base material; and
a die-bonding film provided on the pressure-sensitive adhesive layer,
wherein the pressure-sensitive adhesive layer of the dicing film is an active energy ray-curable heat-expandable pressure-sensitive adhesive layer containing a foaming agent, and
wherein the die-bonding film is constituted by a resin composition containing an epoxy resin.

2. The dicing die-bonding film according to claim 1, wherein the foaming agent is a heat-expandable microsphere.

3. The dicing die-bonding film according to claim 1, wherein the active energy ray-curable heat-expandable pressure-sensitive adhesive layer of the dicing film is formed of an active energy ray-curable heat-expandable pressure-sensitive adhesive containing an acrylic polymer A, the acrylic polymer A being an acrylic polymer having a constitution that a polymer composed of a monomer composition containing 50% by weight or more of an acrylic acid ester represented by CH₂═CHCOOR (wherein R is an alkyl group having 6 to 10 carbon atoms) and 10% by weight to 30% by weight of a hydroxyl group-containing monomer and containing no carboxyl group-containing monomer is addition reacted with an isocyanate compound having a radical-reactive carbon-carbon double bond in an amount of 50 mol % to 95 mol % based on the hydroxyl group-containing monomer; and
wherein the active energy ray-curable heat-expandable pressure-sensitive adhesive layer of the dicing film has a gel fraction after curing by active energy ray irradiation of 90% by weight or more.

4. The dicing die-bonding film according to claim 1, wherein the active energy ray-curable heat-expandable pressure-sensitive adhesive layer of the dicing film is formed of an active energy ray-curable heat-expandable pressure-sensitive adhesive containing an active energy ray-curable pressure-sensitive adhesive capable of forming an active energy ray-curable pressure-sensitive adhesive layer having an elastic modulus in a temperature range of 23° C. to 150° C. of 5×10⁴ Pa to 1×10⁶ Pa, and a foaming agent; and
wherein the die-bonding film has an elastic modulus in a temperature range of T₀ to T₀+20° C. of 1×10⁵ Pa to 1×10¹⁰ Pa, in which T₀ represents a foaming starting temperature of the active energy ray-curable heat-expandable pressure-sensitive adhesive layer of the dicing film.

5. A process for producing a semiconductor device which comprises using the dicing die-bonding film according to claim 1.
